(19) United States
(12) Patent Application Publication
(10) Pub. No.: US 2021/0389184 A1
(43) Pub. Date: Dec. 16, 2021

(54) LIGHT RECEIVING DEVICE

(71) Applicant: SONY SEMICONDUCTOR SOLUTIONS CORPORATION, Atsugi-shi, Kanagawa (JP)

(72) Inventor: Yoshikazu KONDO, Kanagawa (JP)

(21) Appl. No.: 17/290,851

(22) PCT Filed: Sep. 20, 2019
(86) PCT No.: PCT/JP2019/036960

§ 371 Date: May 3, 2021

(30) Foreign Application Priority Data
Nov. 13, 2018 (JP) 2018-212838

(51) Int. Cl. G01J 4/04; H01L 27/146; G02B 5/30

(52) U.S. Cl. CPC G01J 4/04; G02B 5/3058; H01L 27/14625

(57) ABSTRACT

A light receiving device includes a plurality of photoelectric conversion element units 10A₁, 10A₂, 10A₃, and 10A₄ each composed of four types of photoelectric conversion elements including four types of polarization elements 50₁, 50₂, 50₃, and 50₄ and further includes a polarized component measurement unit 91 and a polarized component calculation unit 92, wherein the polarized component measurement unit 91 obtains, for example, a first polarized component and a third polarized component on the basis of output signals from a first photoelectric conversion element and a third photoelectric conversion element, and the polarized component calculation unit 92 calculates, for example, polarized components of a third polarization azimuth and a first polarization azimuth in the first polarized component and the third polarized component on the basis of the obtained third polarized component and the first polarized component.

### TECHNICAL FIELD

The present disclosure relates to a light receiving device, and more specifically, to a light receiving device including polarization elements.

### BACKGROUND ART

In technical fields using polarized light, such as recognition of a three-dimensional shape of a low-contrast object, and stress inspection of a transparent object, polarization information from an object is acquired. That is, photoelectric conversion elements (light receiving elements) constituting a light receiving device (imaging device) include polarization elements, and polarization information is also acquired through the photoelectric conversion elements.

As an important index that defines a polarization information separation performance of a polarization element, an “extinction ratio” can be conceived. It is assumed that an output signal strength from a photoelectric conversion element when a polarization direction of incident light is parallel to a light transmission axis of the polarization element (i.e., the incident light has a polarization direction in which it can pass through the polarization element) is S₁, and light transmissivity of light in a polarization state parallel to the light transmission axis of the polarization element is T₁. In addition, it is assumed that an output signal strength (leak signal strength, absorbed component) from the photoelectric conversion element when the polarization direction of the incident light is perpendicular to the light transmission axis of the polarization element (i.e., the polarization direction of the incident light is parallel to a light absorption axis of the polarization element, in other words, the incident light has a polarization direction in which it cannot pass through the polarization element) is S₂, and light absorptivity of light in a polarization state parallel to the light absorption axis (axis orthogonal to the light transmission axis) of the polarization element is T₂. As illustrated in FIG. 44, an extinction ratio ρₑ is defined as ρₑ=T₁/T₂. The higher the extinction ratio, the higher the polarization information separation performance. In general, levels such as 10 to 20 for authentication, 50 to 100 for shape recognition such as factory automation (FA), intelligent transport systems (ITS), and monitoring, and 500 to 1000 for scientific measurement have become standards.

As a polarization element, a variety of polarization elements are proposed in response to required performance. Among them, a wire grid polarization element can be conceived as a widely used polarization element from the viewpoint of optical transmission loss, thermal properties, and broadband performance (refer to JP H09-090129 A, for example). In the wire grid polarization element, a fine metal wire having a grid width b is periodically arranged at a grid period d, and thus a polarization element having a low loss and a high extinction ratio is realized. In the technology disclosed in this Japanese Patent Application Publication, Au/Al is used as the fine metal wire and approximately 80% as a maximum value of the light transmissivity T₁ and approximately 0.8% as a minimum value of the light absorptivity T₂ are realized in a configuration in which b/d=0.5. That is, a polarization element having a peak performance of an extinction ratio of about 100 is obtained.

### CITATION LIST

### Patent Literature

[PTL 1]

JP H09-090129 A

### SUMMARY

### Technical Problem

However, the extinction ratio of the polarization element and the light transmissivity of the light transmission axis are in a trade-off relationship, and when a high extinction ratio is intended to be obtained, the light transmissivity of the light transmission axis tends to decrease. In the technology disclosed in the aforementioned Japanese Patent Application Publication, the light transmissivity T₁ can be increased by extending the grid period d of the wire grid polarization element, that is, decreasing the value of b/d. On the other hand, a wavelength width that can limit the light absorptivity T₂ to a specific value or lower (a wavelength width that can realize a specific extinction ratio) is reduced. This is caused by the phenomenon that an increase in the grid period d for increasing the light transmissivity T₁ causes leak of a polarized component to be absorbed to increase. In addition, due to the trade-off relationship between the extinction ratio of the polarization element and the light transmissivity of the light transmission axis, the extinction ratio has to be sacrificed in order to increase the light transmissivity T₁ in applications on the assumption of use outdoors or under natural light in which the sensitivity of the polarization element is regarded as important. On the other hand, when the extinction ratio is regarded as important, fields to which the polarization element can be applied are limited with respect to the sensitivity of the polarization element or additional lighting needs to be prepared in order to supplement insufficient sensitivity.

Accordingly, an object of the present disclosure is to provide a light receiving device having a configuration in which polarization information with high accuracy can be obtained as a whole even through photoelectric conversion elements including high-sensitivity polarization elements having much leakage of absorbed components (i.e., polarization elements having a high light transmissivity and a low extinction ratio).

### Solution to Problem

A light receiving device according to a first aspect of the present disclosure to accomplish the aforementioned object includes

a plurality of photoelectric conversion element units each composed of a first photoelectric conversion element including a first polarization element and a second photoelectric conversion element including a second polarization element, and

further includes a polarized component measurement unit and a polarized component calculation unit,

wherein the first polarization element has a first polarization azimuth of an angle of α degrees,

the second polarization element has a second polarization azimuth of an angle of (α+90) degrees,

the polarized component measurement unit obtains a first polarized component of incident light on the basis of an output signal from the first photoelectric conversion element and obtains a second polarized component of the incident light on the basis of an output signal from the second photoelectric conversion element, and

the polarized component calculation unit calculates a polarized component of the second polarization azimuth in the obtained first polarized component on the basis of the obtained second polarized component and calculates a polarized component of the first polarization azimuth in the obtained second polarized component on the basis of the obtained first polarized component.

A light receiving device according to a second aspect of the present disclosure to accomplish the aforementioned object includes

a plurality of photoelectric conversion element units each composed of a first photoelectric conversion element including a first polarization element, a second photoelectric conversion element including a second polarization element, a third photoelectric conversion element including a third polarization element, and a fourth photoelectric conversion element including a fourth polarization element, and

further includes a polarized component measurement unit and a polarized component calculation unit,

wherein the first polarization element has a first polarization azimuth of an angle of α degrees,

the second polarization element has a second polarization azimuth of an angle of (α+45) degrees,

the third polarization element has a third polarization azimuth of an angle of (α+90) degrees,

the fourth polarization element has a fourth polarization azimuth of an angle of (α+135) degrees,

the polarized component measurement unit

obtains a first polarized component of incident light on the basis of an output signal from the first photoelectric conversion element,

obtains a second polarized component of the incident light on the basis of an output signal from the second photoelectric conversion element,

obtains a third polarized component of the incident light on the basis of an output signal from the third photoelectric conversion element, and

obtains a fourth polarized component of the incident light on the basis of an output signal from the fourth photoelectric conversion element, and

the polarized component calculation unit

calculates a polarized component of the third polarization azimuth in the obtained first polarized component on the basis of the obtained third polarized component,

calculates a polarized component of the first polarization azimuth in the obtained third polarized component on the basis of the obtained first polarized component,

calculates a polarized component of the fourth polarization azimuth in the obtained second polarized component on the basis of the obtained fourth polarized component, and

calculates a polarized component of the second polarization azimuth in the obtained fourth polarized component on the basis of the obtained second polarized component.

### BRIEF DESCRIPTION OF DRAWINGS

FIG. 1A and FIG. 1B are schematic plan views of wire grid polarization elements constituting photoelectric conversion elements of four photoelectric conversion element units (one photoelectric conversion element group) in a light receiving device of embodiment 1 and a view schematically illustrating a method of calculating a first polarized component and a second polarized component, respectively.

FIG. 2 is a schematic partial cross-sectional view of the light receiving device of embodiment 1 along arrow A-A of FIG. 4A.

FIG. 3A and FIG. 3B are conceptual plan views of a color filter layer constituting photoelectric conversion elements of the light receiving device of embodiment 1 and a conceptual plan view of photoelectric conversion parts.

FIG. 4 is a schematic plan view of wire grid polarization elements constituting photoelectric conversion elements of the light receiving device of embodiment 1.

FIG. 5 is an equivalent circuit diagram of a photoelectric conversion part in the light receiving device (solid-state imaging device) of embodiment 1.

FIG. 6 is a schematic perspective view of wire grid polarization elements.

FIG. 7 is a schematic perspective view of a modified example of wire grid polarization elements.

FIG. 8A and FIG. 8B are schematic partial cross-sectional views of wire grid polarization elements.

FIG. 9A and FIG. 9B are schematic partial cross-sectional views of wire grid polarization elements.

FIG. 10 is a schematic plan view of wire grid polarization elements constituting a photoelectric conversion element of four photoelectric conversion element units (photoelectric conversion element group) in a light receiving device of embodiment 2.

FIG. 11 is a conceptual plan view of a photoelectric conversion element of the light receiving device of embodiment 2.

FIG. 12 is a diagram schematically illustrating a method of calculating a polarized component in the light receiving device of embodiment 2.

FIG. 13 is a diagram schematically illustrating a method of calculating a polarized component in the light receiving device of embodiment 2.

FIG. 14 is a schematic plan view of wire grid polarization elements constituting each photoelectric conversion element of 2×6=12 photoelectric conversion element units in a light receiving device of embodiment 3.

FIG. 15 is a schematic partial cross-sectional view of the light receiving device of embodiment 3 along arrow A-A of FIG. 17.

FIG. 16 is a conceptual plan view of a photoelectric conversion part in the light receiving device of embodiment 3.

FIG. 17 is a schematic plan view of wire grid polarization elements constituting a photoelectric conversion element of the light receiving device of embodiment 3.

FIG. 18 is a schematic plan view of a photoelectric conversion element group in the light receiving device of embodiment 3.

FIG. 19 is a schematic plan view of wire grid polarization elements constituting each photoelectric conversion element of 2×6=12 photoelectric conversion element units in a modified example of the light receiving device of embodiment 3.

FIG. 20A and FIG. 20B are schematic partial plan views of a wavelength selection means (color filter layer) and a wire grid polarization element in a first modified example of the light receiving device of embodiment 1.

FIG. 21 is a schematic partial plan view of a photoelectric conversion element in the first modified example of the light receiving device of embodiment 1.

FIG. 22A and FIG. 22B are schematic partial plan views of a wavelength selection means (color filter layer) and a wire grid polarization element in a second modified example of the light receiving device of embodiment 1.

FIG. 23A and FIG. 23B are schematic partial plans view of a photoelectric conversion element in the second modified example of the light receiving device of embodiment 1 and a schematic partial plan view of a wire grid polarization element in the second modified example of the light receiving device of embodiment 1.

FIG. 24A and FIG. 24B are schematic partial plan views of a wavelength selection means (color filter layer) and a wire grid polarization element in a third modified example of the light receiving device of embodiment 1.

FIG. 25A and FIG. 25B are schematic partial plans view of a photoelectric conversion element in the third modified example of the light receiving device of embodiment 1 and a schematic partial plan view of a wire grid polarization element in the third modified example of the light receiving device of embodiment 1.

FIG. 26A and FIG. 26B are schematic partial plan views of a wavelength selection means (color filter layer) and a wire grid polarization element in a fifth modified example of the light receiving device of embodiment 1.

FIG. 27 is a schematic partial plan view of a photoelectric conversion element in the fifth modified example of the light receiving device of embodiment 1.

FIG. 28 is a plane layout diagram of a modified example of photoelectric conversion elements in a Bayer arrangement.

FIG. 29 is a plane layout diagram of a modified example of photoelectric conversion elements in a Bayer arrangement.

FIG. 30 is a plane layout diagram of a modified example of photoelectric conversion elements in a Bayer arrangement.

FIG. 31 is a plane layout diagram of a modified example of photoelectric conversion elements in a Bayer arrangement.

FIG. 32 is a plane layout diagram of a modified example of photoelectric conversion elements in a Bayer arrangement.

FIG. 33 is a plane layout diagram of a modified example of photoelectric conversion elements in a Bayer arrangement.

FIG. 34 is a plane layout diagram of a modified example of photoelectric conversion elements in a Bayer arrangement.

FIG. 35 is a plane layout diagram of a modified example of photoelectric conversion elements in a Bayer arrangement.

FIG. 36 is a plane layout diagram of a modified example of photoelectric conversion elements in a Bayer arrangement.

FIG. 37 is a plane layout diagram of a modified example of photoelectric conversion elements in a Bayer arrangement.

FIG. 38 is a plane layout diagram of a modified example of photoelectric conversion elements in a Bayer arrangement.

FIG. 39 is a plane layout diagram of a modified example of photoelectric conversion elements in a Bayer arrangement.

FIG. 40 is a plane layout diagram of a modified example of photoelectric conversion elements in a Bayer arrangement.

FIG. 41 is a conceptual diagram of a solid-state imaging device in a case where a light receiving device of the present disclosure is applied to the solid-state imaging device.

FIG. 42 is a conceptual diagram of an electronic device (camera) that is a solid-state imaging device to which the light receiving device of the present disclosure is applied.

FIG. 43A, FIG. 43B, FIG. 43C, and FIG. 43D are schematic partial cross-sectional views of an underlying insulating film and the like for describing a method for manufacturing wire grid polarization elements constituting the light receiving device of the present disclosure.

FIG. 44 is a conceptual diagram for describing an extinction ratio.

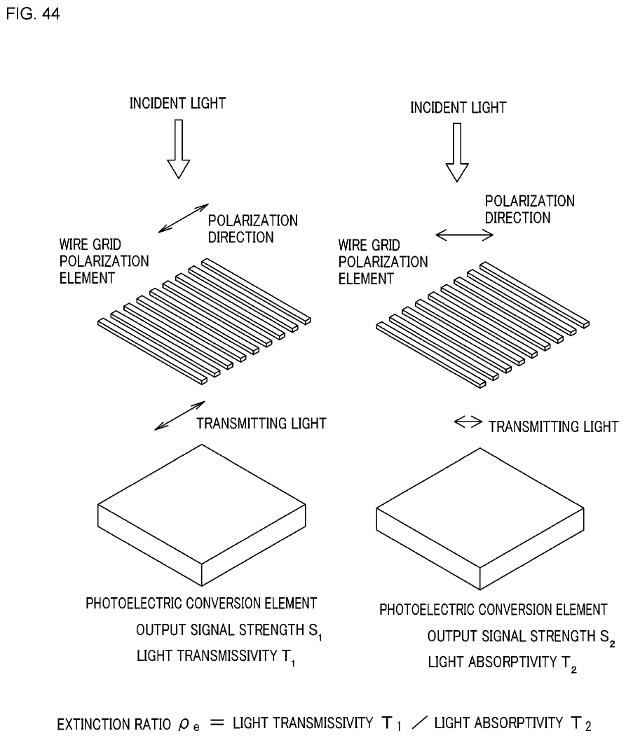

FIG. 45 is a conceptual diagram for describing light and the like which pass through a wire grid polarization element.

### DESCRIPTION OF EMBODIMENTS

Hereinafter, the present disclosure will be described on the basis of embodiments with reference to the drawings, but the present disclosure is not limited to embodiments and various numerical values and materials in embodiments are examples. Meanwhile, description will be performed in the following order.

1. Description of overview of light receiving devices according to first and second aspects of the present disclosure

2. Embodiment 1 (light receiving device according to second aspect of the present disclosure)

3. Embodiment 2 (modification of embodiment 1)

4. Embodiment 3 (light receiving device according to first aspect of the present disclosure)

5. Others

<Description of Overview of Light Receiving Devices According to First and Second Aspects of the Present Disclosure>

In a light receiving device according to the first aspect of the present disclosure, a polarized component calculation unit

may calculate a corrected first polarized component by subtracting a value obtained by multiplying an obtained value of a polarized component of a second polarization azimuth by a reciprocal of an extinction ratio from an obtained value of a first polarized component and calculate a corrected second polarized component by subtracting a value obtained by multiplying an obtained value of a polarized component of a first polarization azimuth by the reciprocal of the extinction ratio from an obtained value of a second polarized component.

In addition, in the light receiving device of the present disclosure including such a desirable form, a first photoelectric conversion element and a second photoelectric conversion element may be arranged in one direction (e.g., they neighbor each other).

In a light receiving device according to the second aspect of the present disclosure, a polarized component calculation unit

may calculate a corrected first polarized component by subtracting a value obtained by multiplying an obtained value of a polarized component of a third polarization azimuth by a reciprocal of an extinction ratio from an obtained value of a first polarized component,

calculate a corrected third polarized component by subtracting a value obtained by multiplying an obtained value of a polarized component of a first polarization azimuth by the reciprocal of the extinction ratio from an obtained value of a third polarized component,

calculate a corrected second polarized component by subtracting a value obtained by multiplying an obtained value of a polarized component of a fourth polarization azimuth by the reciprocal of the extinction ratio from an obtained value of a second polarized component, and

calculate a corrected fourth polarized component by subtracting a value obtained by multiplying an obtained value of a polarized component of a second polarization azimuth by the reciprocal of the extinction ratio from an obtained value of a fourth polarized component.

The light receiving device according to the second aspect of the present disclosure including the aforementioned desirable form may employ a configuration in which

a plurality of photoelectric conversion elements are arranged in a two-dimensional matrix form in an x₀ direction and a y₀ direction,

a photoelectric conversion element unit includes a single first photoelectric conversion element, a single second photoelectric conversion element, a single third photoelectric conversion element, and a single fourth photoelectric conversion element,

the first photoelectric conversion element and the second photoelectric conversion element are arranged in the x₀ direction,

the third photoelectric conversion element and the fourth photoelectric conversion element are arranged in the x₀ direction,

the first photoelectric conversion element and the fourth photoelectric conversion element are arranged in the y₀ direction, and

the second photoelectric conversion element and the third photoelectric conversion element are arranged in the y₀ direction.

Alternatively, the light receiving device according to the second aspect of the present disclosure including the aforementioned desirable form may employ a configuration in which

the plurality of photoelectric conversion elements are arranged in a two-dimensional matrix form in the x₀ direction and the y₀ direction,

a photoelectric conversion element unit includes a single first photoelectric conversion element, two second photoelectric conversion elements including a (2-A)-th photoelectric convention element and a (2-B)-th photoelectric conversion element, four third photoelectric conversion elements including a (3-A)-th photoelectric convention element, a (3-B)-th photoelectric conversion element, a (3-C)-th photoelectric convention element, and a (3-D)-th photoelectric conversion element, and two fourth photoelectric conversion elements including a (4-A)-th photoelectric convention element and a (4-B)-th photoelectric conversion element,

the (3-A)-th photoelectric conversion element, the (4-A)-th photoelectric conversion element, and the (3-B)-th photoelectric conversion element are arranged adjacently in the x₀ direction,

the (2-A)-th photoelectric conversion element, the first photoelectric conversion element, and the (2-B)-th photoelectric conversion element are arranged adjacently in the x₀ direction,

the (3-C)-th photoelectric conversion element, the (4-B)-th photoelectric conversion element, and the (3-D)-th photoelectric conversion element are arranged adjacently in the x₀ direction,

the (3-A)-th photoelectric conversion element, the (2-A)-th photoelectric conversion element, and the (3-C)-th photoelectric conversion element are arranged adjacently in the y₀ direction,

the (4-A)-th photoelectric conversion element, the first photoelectric conversion element, and the (4-B)-th photoelectric conversion element are arranged adjacently in the y₀ direction, and

the (3-B)-th photoelectric conversion element, the (2-B)-th photoelectric conversion element, and the (3-D)-th photoelectric conversion element are arranged adjacently in the y₀ direction.

In the light receiving devices according to the first and second aspects of the present disclosure including the aforementioned desirable forms and configurations, a polarization element can be configured as a wire grid polarization element. In addition, in this case, it is desirable that light transmissivity along a light transmission axis of the wire grid polarization element be equal to or greater than 80%. Further, an upper limit of the light transmissivity may be 90% although it is not limited thereto. In addition, an extinction ratio of the wire grid polarization element or an extinction ratio as a photoelectric conversion element may be equal to or greater than 10 and equal to or less than 1000.

In the light receiving device of the present disclosure including the above-described various desirable forms and configurations (which may be collectively called simply “a light receiving device and the like of the present disclosure” hereinafter), each photoelectric conversion element has a photoelectric conversion part on a light emitting side of a polarization element. In the light receiving device and the like of the present disclosure, a polarized component measurement unit and a polarized component calculation unit can be configured as known circuits.

In the light receiving device according to the second aspect of the present disclosure including the above-described various desirable forms and configurations, although the plurality of photoelectric conversion elements are arranged in a two-dimensional matrix form, it is desirable that the x₀ direction and the y₀ direction be orthogonal, and in this case, the x₀ direction is a so-called row direction or a so-called column direction and the y₀ direction is the column direction or the row direction. In addition, in the light receiving device and the like of the present disclosure, the photoelectric conversion element units or photoelectric conversion element groups which will be described later may be arranged in a two-dimensional matrix form in the x₀ direction and the yo direction.

In the light receiving device and the like of the present disclosure, a wire grid polarization element may have a form in which a plurality of laminated structures each including at least a band-shaped light reflection layer and light absorption layer (the light reflection layer is positioned on a light incident side) are spaced and arranged in parallel (i.e., a form having a line-and-space structure). Alternatively, the wire grid polarization element may have a form in which a plurality of laminated structures each including a band-shaped light reflection layer, insulating film, and light absorption layer (the light absorption layer is positioned on a light incident side) are spaced and arranged in parallel. Further, in this case, a configuration in which the light reflection layer and the light absorption layer are separated by the insulating film in the laminated structure (i.e., a configuration in which the insulating film is formed on the overall top face of the light reflection layer and the light absorption layer is formed on the overall top face of the insulating film) may be employed, or a configuration in which a part of the insulating film is cut out and the light reflection layer and the light absorption layer come into contact with each other in the cut part of the insulating film may be employed. In addition, in such cases, the light reflection layer may be formed of a first conductive material and the light absorption layer may be formed of a second conductive material. By employing such a configuration, the overall area of the light reflection layer and the light absorption layer can be electrically connected to an area having an appropriate electric potential in the light receiving device, and thus it is possible to surely avoid generation of a problem that the wire grid polarization element is charged at the time of formation thereof, and as a result of occurrence of a kind of discharging, the wire grid polarization element and a photoelectric conversion part are damaged. Alternatively, the wire grid polarization element may employ a configuration in which the insulating film is omitted and the light absorption layer and the light reflection layer are laminated from the light incident side.

This wire grid polarization element may be manufactured, for example, on the basis of processes of

(A) forming a photoelectric conversion part and then providing a light reflection formation layer formed of the first conductive material and electrically connected to a substrate or the photoelectric conversion part, for example,

(B) providing an insulating film formation layer on the light reflection layer formation layer and providing a light absorption layer formation layer formed of the second conductive material and having at least a part thereof in contact with the light reflection layer formation layer on the insulating film formation layer, and then

(C) patterning the light absorption formation layer, the insulating film formation layer, and the light reflection layer formation layer to obtain a wire grid polarization element in which a plurality of line parts each including a band-shaped light reflection layer, insulating film, and light absorption layer are spaced and arranged in parallel.

Further, the light absorption layer formation layer formed of the second conductive material may be provided in a state in which the light reflection layer formation layer has been set to a predetermined electric potential through the substrate or the photoelectric conversion part in process (B), and

the light absorption layer formation layer, the insulating film formation layer, and the light reflection layer formation layer may be patterned in a state in which the light reflection layer formation layer has been set to a predetermined electric potential through the substrate or the photoelectric conversion part in process (C).

In addition, a configuration in which an underlying film is formed under the light reflection layer may be employed. Accordingly, roughness of the light reflection layer formation layer and the light reflection layer can be improved. As a material forming the underlying film (barrier metal layer), Ti, TiN, or a laminated structure of Ti/TiN may be conceived.

In the wire grid polarization element in the light receiving device and the like of the present disclosure, a configuration in which a direction in which the band-shaped laminated structure extends is consistent with a polarization azimuth for extinction and a direction in which the band-shaped laminated structure is repeated is consistent with a polarization azimuth for transmission may be employed. That is, the light reflection layer has a function as a polarizer, attenuates a polarized wave (either one of TE wave/S wave and TM wave/P wave) having an electric field component in a direction parallel to the direction in which the laminated structure extends, and transmits a polarized wave (another of TE wave/S wave and TM wave/P wave) having an electric field component in a direction orthogonal to the direction in which the laminated structure extends (a direction in which the band-shaped laminated structure is repeated) in light incident on the wire grid polarization element. That is, the direction in which the laminated structure extends becomes a light absorption axis of the wire grid polarization element and the direction orthogonal to the direction in which the laminated structure extends becomes a light transmission axis of the wire grid polarization element. There are cases in which the direction in which the band-shaped laminated structure (i.e., constituting a line part of a line-and-space structure) is referred to as a “first direction” for convenience and the direction in which the band-shaped laminated structure (line part) is repeated (the direction orthogonal to the direction in which the band-shaped laminated structure extends) is referred to as a “second direction” for convenience.

The second direction may be parallel to the x₀ direction or the y₀ direction. Although an angle between the aforementioned α and the second direction may be inherently any angle, 0 degrees or 90 degrees may be conceived. However, the angle is not limited thereto.

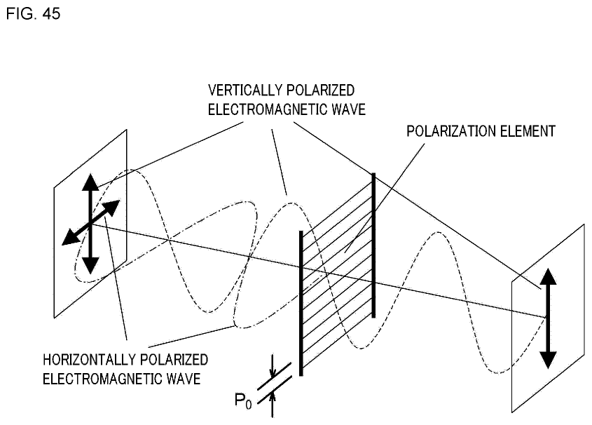

As illustrated in the conceptual diagram of FIG. 45, when a wire grid polarization element formation pitch P₀ is significantly less than a wavelength λ₀ of incident electromagnetic waves, electromagnetic waves vibrating in a plane parallel to the wire grid polarization element extending direction (first direction) are selectively reflected/absorbed by wire grid polarization elements. Here, while a distance between lines parts (a distance of a space part in the second direction, length) is set to the wire grid polarization element formation pitch P₀, it corresponds to a value (d−b) obtained by subtracting the grid width b from the grid period d in the aforementioned wire grid polarization element. Then, electromagnetic waves (light) arriving at wire grid polarization elements include a vertically polarized component and a horizontally polarized component, as illustrated in FIG. 45, but electromagnetic waves that have passed through the wire grid polarization elements become linearly polarized light in which the vertically polarized component is dominant. Here, considering a visible light wavelength range, when the wire grid polarization element formation pitch P₀ is considerably less than an effective wavelength λ_{eff} of electromagnetic waves incident on the wire grid polarization elements, polarized components biased to a plane parallel to the first direction are reflected or absorbed on the surface of the wire grid polarization elements. On the other hand, when electromagnetic waves having polarized components biased to a plane parallel to the second direction are incident on the wire grid polarization elements, electric fields that have propagated on the surface of the wire grid polarization elements transmit (emit) from the backside of the wire grid polarization elements having the same wavelengths and the same polarization azimuth as those of the incident wavelength. Here, when an average refractive index obtained on the basis of materials present in space parts is set to nₐᵥₑ, the effective wavelength λ_{eff} is represented by λ₀/nₐᵥₑ. The average refractive index nₐᵥₑ is a value obtained by adding up products of refractive indexes and volumes of the materials present in the space parts and dividing the addition result by the volume of the space parts. When the value of the wavelength λ₀ is fixed, the value of the effective wavelength λ_{eff} increases as the value of nₐᵥₑ decreases and thus the value of the formation pitch P₀ can be increased. In addition, as the value of nₐᵥₑ increases, the light transmissivity in the wire grid polarization elements decreases to cause reduction in the extinction ratio.

In the light receiving device and the like of the present disclosure, light is incident from the light absorption layer. In addition, the wire grid polarization element attenuates a polarized wave (either one of TE wave/S wave and TM wave/P wave) having an electric field component parallel to the first direction and transmits a polarized wave (another one of TE wave/S wave and TM wave/P wave) having an electric field component parallel to the second direction by using four operations of transmission, reflection, and interference of light, and selective light absorption of polarized waves according to optical anisotropy. That is, one polarized wave (e.g., TE wave) is attenuated by the selective light absorption operation for polarized waves according to optical anisotropy of the light absorption layer. The band-shaped light reflection layer serves as a polarizer and one polarized wave (e.g., TE wave) that has passed through the light absorption layer and the insulating film is reflected by the light reflection layer. Here, if the insulating film is configured such that the phase of one polarized wave (e.g., TE wave) that has transmitted the light absorption layer and has been reflected by the light reflection layer is shifted by a half wavelength, one polarized wave (e.g., TE wave) reflected by the light reflection layer is attenuated by being canceled due to interference with one polarized wave (e.g., TE wave) reflected by the light absorption layer. In this manner, one polarized wave (e.g., TE wave) can be selectively attenuated. However, it is possible to realize improvement of contrast even when the thickness of the insulating film is not optimized, as described above. Accordingly, the thickness of the insulating film may be determined on the basis of balance between desired polarization properties and an actual manufacturing process for practical purposes.

In the following description, there are cases in which a laminated structure constituting a wire grid polarization element provided above the photoelectric conversion part is referred to as a “first laminated structure” for convenience and a laminated structure surrounding the first laminated structure is referred to as a “second laminated structure” for convenience. The second laminated structure connects a wire grid polarization element (first laminated structure) constituting a certain photoelectric conversion element and a wire grid polarization element (first laminated structure) constituting a photoelectric conversion element neighboring the certain photoelectric conversion element. The second laminated structure can be composed of a laminated structure having the same configuration as the laminated structure constituting the wire grid polarization element (i.e., a so-called solid film structure that is the second laminated structure composed of at least a light reflection layer and a light absorption layer, for example, a light reflection layer, an insulating film, and a light absorption layer and has not a line-and-space structure). The second laminated structure may have the line-and-space structure like the wire grid polarization element if it does not serve as the wire grid polarization element. That is, it may have a configuration in which the wire grid formation pitch P₀ is sufficiently greater than the effective wavelength of incident electromagnetic waves. A frame part which will be described layer may be composed of the second laminated structure. In some cases, the frame part may be composed of the first laminated structure. It is desirable that the frame part be connected to the line part of the wire grid polarization element. The frame part may also be cased to serve as a light-shielding part.

The light reflection layer (light reflection layer formation layer) may be formed of a metal material, an alloy material, or a semiconductor material and the light absorption layer may be formed of a metal material, an alloy material, or a semiconductor material. Specifically, as an inorganic material forming the light reflection layer (light reflection layer formation layer), specifically, a metal material such as aluminum (Al), silver (Ag), gold (Au), copper (Cu), platinum (Pt), molybdenum (Mo), chrome (Cr), titanium (Ti), nickel (Ni), tungsten (W), iron (Fe), silicon (Si), germanium (Ge), or tellurium (Te), an alloy material including these metals, or a semiconductor material may be conceived.

As a material forming the light absorption layer (or light absorption layer formation layer), a metal material, an alloy material, or a semiconductor material having a non-zero extinction coefficient k, that is, having light absorption operation, specifically, a metal material such as aluminum (Al), silver (Ag), gold (Au), copper (Cu), molybdenum (Mo), chrome (Cr), titanium (Ti), nickel (Ni), tungsten (W), iron (Fe), silicon (Si), germanium (Ge), tellurium (Te), or tin (Sn), an alloy material including these metals, or a semiconductor material may be conceived. In addition, a silicide based material such as FeSi₂ (particularly, ß-FeSi₂), MgSi₂, NiSi₂, BaSi₂, CrSi₂, or CoSi₂ may also be conceived. In particular, it is possible to obtain high contrast (appropriate extinction ratio) in a visible region by using aluminum or an alloy thereof, or a semiconductor material including ß-FeSi₂, germanium, and tellurium as a material forming the light absorption layer (light absorption layer formation layer). Meanwhile, to cause wavelength bands other than the visible region, for example, an infrared region to have the polarization property, it is desirable to use silver (Ag), copper (Cu), gold (Au), or the like as a material forming the light absorption layer (light absorption layer formation layer) because resonance wavelengths of these metals are close to the infrared region.

The light reflection layer formation layer and the light absorption layer formation layer may be formed on the basis of known methods such as various chemical vapor deposition methods (CVD methods), coating methods, various physical vapor deposition methods (PVD methods) including a sputtering method and a vacuum evaporation method, a sol-gel method, a plating method, an MOCVD method, and an MBE method. In addition, as a method for pattering the light reflection layer formation layer and the light absorption layer formation layer, a combination of a lithography technique and an etching technique (e.g., an anisotropic dry etching technique using carbon tetrafluoride gas, sulfur hexafluoride gas, trifluoromethane gas, or xenon difluoride gas, and a physical etching technique), a so-called lift-off technique, and a so-called self-align double patterning technique using a sidewall as a mask may be conceived. As a lithography technique, photolithography techniques (lithography techniques using g-line and i-line of a high-pressure mercury-vapor lamp, KrF excimer laser, ArF excimer laser, EUV, and the like as light sources, and immersion lithography technique, electron beam lithography technique, and X-ray lithography thereof) may be conceived. Alternatively, the light reflection layer and the light absorption layer may also be formed on the basis of a fine processing technology using an ultrashort pulsed laser such as femtosecond laser, and a nanoimprint method.

As materials forming the insulating film (or insulating film formation layer), an interlayer insulating layer, an underlying insulating layer, and a planarization layer, insulating materials that are transparent for incident light and do not have a light absorption property, specifically, SiOₓ-based materials (materials forming a silicon oxide film) such as silicon oxide (SiO₂), NSG (nondoped silicate glass), BPSG (boron phosphorus silicate glass), PSG, BSG, PbSG, AsSG, SbSG, and SOG (spin on glass), SiN, silicon oxide nitride (SiON), SiOC, SiOF, SiCN, low dielectric constant insulating materials (e.g., fluorocarbon, cycloperfluorocarbon polymer, benzocyclobutene, cyclic fluororesin, polytetrafluoroethylene, amorphous tetrafluoroethylene, polyarylether, arylether fluoride, fluorinated polyimide, organic SOG, parylene, fullerene fluoride, and amorphous carbon), polyimide-based resins, fluorine-based resins, Silk (which is the trademark of The Dow Chemical Co. and a coating type low dielectric constant interlayer insulating film material), Flare (which is the trademark of Honeywell Electronic Materials Co. and a polyarylether (PAO-based material) may be conceived, and there materials may be used alone or in combination. Alternatively, polymethyl methacrylate (PMMA); polyvinyl phenol (PVP); polyvinyl alcohol (PVA); polyimide; polycarbonate (PC); polyethylene terephthalate (PET); polystyrene; silanols (silane coupling agent) such as N-2(aminotethyl)3-aminopropyltrimethoxysilane (AEAPTMS), 3-mercaptopropyl trimethoxy silane (MPTMS), and octadecyltrichlorosilane (OTS); novolac type phenol resin; fluorine-based resin; and organic insulating materials (organic polymer) exemplified as straight-chain hydrocarbons having a functional group that can be coupled to a control electrode at one end, such as octadecanethiol and dodecyl isocyanate, may be conceived, and combinations thereof may be used. The insulating film formation layer may be formed on the basis of known methods such as various CVD methods, a coating method, various PVD methods including the sputtering method and the vacuum evaporation method, various printing methods such as a screen printing method, and a sol-gel method. The insulating film serves as an underlying layer of the light absorption layer and is formed for the purpose of adjusting phases of polarized light that has been reflected by the light absorption layer and polarized light that has transmitted the light absorption layer and has been reflected by the light reflection layer, promoting optimization of an extinction ratio and a light transmissivity according to interference effect, and reducing a reflectivity. Accordingly, it is desirable that the insulating film have a thickness for causing the phases to be shifted by a half wavelength through one reciprocation. However, the light absorption layer has the light absorption effect and thus reflected light is absorbed thereby. Accordingly, it is possible to realize optimization of the extinction ratio even if the thickness of the insulating film is not optimized as described above. Therefore, the thickness of the insulating film may be determined on the basis of balance between a desired polarization property and an actual manufacturing process for practical purposes and, for example, 1×10⁻⁹ m to 1×10⁻⁷ m, more desirably, 1×10⁻⁸ m to 8×10⁻⁸ m may be exemplified. Further, it is desirable that the refractive index of the insulating film be greater than 1.0 and equal to or less than 2.5 although it is not limited thereto.

The light receiving device and the like of the present disclosure may have a form in which a space part of the wire grid polarization element is a void (i.e., a form in which the space part is filled with at least the air). By forming the space part of the wire grid polarization element as a void in this manner, the value of the average reflective index nₐᵥₑ can be reduced, and thus improvement of the light transmissivity and optimization of the extinction ratio in the wire grid polarization element can be promoted. In addition, since the value of the formation pitch P₀ can be increased, it is possible to promote improvement of the manufacturing yield of the wire grid polarization element. A protective film may be formed on the wire grid polarization element, and thus a photoelectric conversion element and a light receiving device having high reliability can be provided. By providing the protective film, it is possible to improve reliability such as improvement of resistance to moisture of the wire grid polarization element. The thickness of the protective film may be in a range that does not affect the polarization property. Since a reflectivity for incident light also varies according to the optical thickness of the protective film (refractive index×protective film thickness), the material and the thickness of the protective film may be determined in consideration of this, and 15 nm or less may be exemplified or ¼ or less of a distance between laminated structures may be exemplified as a thickness. As a material forming the protective film, a material having a reflective index of 2 or less and an extinction coefficient close to zero is desirable, and insulating materials such as SiO₂ including TEOS-SiO₂, SiON, SiN, SiC, SiOC, and SiCN, and metal oxide such as aluminum oxide (AlOₓ), hafnium oxide (HfOₓ), zirconium oxide (ZrOₓ), and tantalum oxide (TaOₓ) may be conceived. Alternatively, perfluorodecyltrichlorosilane and octadecyltrichlorosilane may be conceived. Although the protective film may be formed through known processes such as various CVD methods, a coating method, various PVD methods including the sputtering method and the vacuum evaporation method, and a sol-gel method, it is more desirable to employ a so-called atomic layer deposition (ALD) method or high density plasma chemical vapor deposition (HDP-CVD) method. It is possible to conformally form a thin protective film on the wire grid polarization element by employing the ALD method or the HDP-CVD method. Although the protective film can be formed on the overall surface of wire grid polarization elements, the protective film may be formed only on the sides of the wire grid polarization elements and may not formed on an underlying insulating layer positioned between wire grid polarization elements. In addition, by forming the protective film such that it covers sides that are parts at which metal materials and the like forming the wire grid polarization elements are exposed in this manner, it is possible to block moisture and organic matters in atmosphere to securely curb generation of problems such as corrosion and abnormal precipitation of metal materials and the like forming the wire grid polarization elements. Further, it is possible to promote improvement of long-term reliability of photoelectric conversion elements and provide photoelectric conversion elements including on-chip wire grid polarization elements with higher reliability

In addition, when the protective film is formed on the wire grid polarization elements, a second protective film may be formed between the wire grid polarization elements and the protective film, and

when the refractive index of the material forming the protective film is n₁′ and the refractive index of the material forming the second protective film is n₂′, n₁′>n₂′ may be satisfied. It is possible to surely decrease the value of the average refractive index nₐᵥₑ by satisfying n₁′>n₂′. Here, it is desirable that the protective film be formed of SiN and the second protective film be formed of SiO₂ or SiON.

Further, a third protective film may be formed at least on the side of a line part facing a space part of the wire grid polarization element. That is, the space part is filled with the air and the third protective film is additionally present in the space part. Here, as a material forming the third protective film, a material having a reflective index of 2 or less and an extinction coefficient close to zero is desirable, and insulating materials such as SiO₂ including TEOS-SiO₂, SiON, SiN, SiC, SiOC, and SiCN, and metal oxide such as aluminum oxide (AlOₓ), hafnium oxide (HfOₓ), zirconium oxide (ZrOₓ), and tantalum oxide (TaOₓ) may be conceived. Alternatively, perfluorodecyltrichlorosilane and octadecyltrichlorosilane may be conceived. Although the third protective film may be formed through known processes such as various CVD methods, a coating method, various PVD methods including the sputtering method and the vacuum evaporation method, and a sol-gel method, it is more desirable to employ the ALD method or the high density plasma chemical vapor deposition (HDP-CVD) method. Although it is possible to conformally form a thin third protective film on the wire grid polarization element by employing the ALD method, it is more desirable to employ the HDP-CVD method from the viewpoint of formation of a further thinner third protective film on the side of the line part. Alternatively, if the space part is filled with a material forming the third protective film and a void, a hole, a cavity, or the like is provided in the third protective film, the overall refractive index of the third protective film can be reduced.

When metal materials or alloy materials (there are cases in which “metal material and the like” hereinafter) forming the wire grid polarization material are exposed to the outside air, corrosion resistance of the metal material and the like may deteriorate due to adhesion of moisture and organic matters from the outside air and long-term reliability of the photoelectric conversion part may deteriorate. In particular, when moisture adheres to the line part (laminated structure) composed of a metal material and the like-insulating material-metal material and the like, CO₂ and O₂ have been dissolved in the moisture and thus this operates as an electrolyte so that a local battery may be formed between two types of metals. When this phenomenon occurs, a reduction reaction such as generation of hydrogen proceeds on a cathode (positive electrode) side and an oxidation reaction proceeds on an anode (negative electrode) side, and thus abnormal precipitation of the metal material and the like and shape change in the wire grid polarization element occur. As a result, originally expected performances of the wire grid polarization element and the photoelectric conversion part may be impaired. For example, when aluminum (Al) is used for the light reflection layer, abnormal precipitation of aluminum may occur as represented by the reaction formula below. However, if the protective film is formed, moreover, if the third protective film is formed, generation of such a problem can be surely avoided.

Al→Al³⁺+3e⁻

Al³⁺+3OH⁻→Al(OH)₃

In the light receiving device and the like of the present disclosure, although the length of the light reflection layer in the first direction may be the same as a length of a photoelectric conversion region that is a region where substantial photoelectric conversion of the photoelectric conversion element is performed in the first direction, may also be the same as the length of the photoelectric conversion element, or may be an integer multiple of the length of the photoelectric conversion element in the first direction, it is not limited thereto.

In the light receiving device and the like of the present disclosure, on chip microlenses (OCL) may be provided above the wire grid polarization elements. Alternatively, a structure in which sub-on-chip microlenses (inner lenses, OPA) are provided above the wire grid polarization elements and main on-chip microlenses are provided on the sub-on-chip microlenses (OPA) may be employed. In addition, in such a configuration, a wavelength selection means (specifically, a known color filter layer, for example) may be disposed between the wire grid polarization elements and the on-chip microlenses. By employing this configuration, it is possible to promote independent optimization of wire grid polarization elements in wavelength bands of transmitted light in respective wire grid polarization elements and realize lower reflectivity in the entire visible region. A configuration in which a planarization film is formed between the wire grid polarization elements and the wavelength selection means and an underlying insulating layer formed of an inorganic material, such as a silicon oxide film, and serving as a process foundation in wire grid polarization element manufacturing processes is formed under the wire grid polarization elements may be employed. When the main on-chip microlenses are provided above the sub-on-chip microlenses (OPA), a configuration in which the wavelength selection means (a known color filter layer) is disposed between the sub-on-chip microlenses and the main on-chip microlenses may be employed.

As a color filter layer, for example, not only a color filter layer that transmits light in a first wavelength range such as red light, light in a second wavelength range or a third wavelength range such as green light, and light in a fourth wavelength range such as blue light but also a color filter layer that transmits specific wavelengths such as cyan, magenta, and yellow may be conceived, or a color filter layer that does not transmit lights in the first wavelength range, the second wavelength range, and the third wavelength range may be conceived. In addition, when color separation or light separation is not a purpose, or in a photoelectric conversion element having sensitivity to a specific wavelength, the color filter layer may be unnecessary. When a photoelectric conversion element in which the color filter layer is provided and a photoelectric conversion element in which the color filter layer is not provided coexist, in the photoelectric conversion element in which the color filter layer is not provided, a transparent resin layer instead of the color filter layer may be formed in order to secure flatness with respect to the photoelectric conversion element in which the color filter layer is provided. The color filter layer may also be configured as not only an organic material-based color filter layer using an organic compound such as a pigment or a dye but also a wavelength selection element using photonic crystal and plasmon (a color filter layer having a conductive lattice structure in which a lattice-shaped hole structure is provided in a conductive thin film. Refer to JP 2008-177191A, for example), or a thin film formed of an inorganic material such as amorphous silicon.

For example, a plurality of various wirings (wiring layers) formed of aluminum (Al) or copper (Cu) may be formed under the wire grid polarization elements in order to drive photoelectric conversion elements. In addition, the wire grid polarization elements are connected to a semiconductor substrate via the various wirings (wiring layers) and contact hole parts, and thus a predetermined electric potential can be applied to the wire grid polarization elements. Specifically, the wire grid polarization elements may be grounded, for example. As the semiconductor substrate, a silicon semiconductor substrate and a compound semiconductor substrate such as an InGaAs substrate may be conceived. The photoelectric conversion part is formed in the semiconductor substrate or above the semiconductor substrate.

When imaging elements are composed of photoelectric conversion elements, configurations and structures of a floating diffusion layer, an amplification transistor, a reset transistor, and a select transistor which constitute a controller for controlling driving of the imaging elements may be the same as configurations and structures of a floating diffusion layer, an amplification transistor, a reset transistor, and a select transistor of a conventional controller. A driving circuit may also have a known configuration and structure.

A waveguide structure or a light-concentrating tube structure may be provided between photoelectric conversion elements, and thus reduction of optical crosstalk can be promoted. Here, the waveguide structure is formed of a thin film that is formed in a region (e.g., a cylindrical region) positioned between photoelectric conversion parts in an interlayer insulating layer covering photoelectric conversion parts and has a refractive index having a value greater than a value of a refractive index of a material forming the interlayer insulating layer, and light incident from above the photoelectric conversion parts is total-reflected on this thin film to reach the photoelectric conversion parts. That is, an orthographic projection image of the photoelectric conversion parts with respect to the substrate is positioned inside an orthographic projection image of the thin film forming the waveguide structure with respect to the substrate, and the orthographic projection image of the photoelectric conversion parts with respect to the substrate is surrounded by the orthographic projection image of the thin film forming the waveguide structure with respect to the substrate. In addition, the light-concentrating tube structure is formed of a light-shielding thin film that is formed in a region (e.g., a cylindrical region) positioned between photoelectric conversion parts in an interlayer insulating layer covering photoelectric conversion parts and made of a metal material or an alloy material, and light incident from above the photoelectric conversion parts is total-reflected on this thin film to reach the photoelectric conversion parts. That is, an orthographic projection image of the photoelectric conversion parts with respect to the substrate is positioned inside an orthographic projection image of the thin film forming the light-concentrating tube structure with respect to the substrate, and the orthographic projection image of the photoelectric conversion parts with respect to the substrate is surrounded by the orthographic projection image of the thin film forming the light-concentrating tube structure with respect to the substrate.

In the light receiving device and the like of the present disclosure, one pixel may be composed of a plurality of subpixels. In addition, each subpixel may include one or more photoelectric conversion elements, for example. A relationship between a pixel and a subpixel will be described later. A configuration and a structure of the photoelectric conversion elements or photoelectric conversion parts themselves may be a known configuration and structure.

All photoelectric conversion elements constituting the light receiving device of the present disclosure may include wire grid polarization elements or some photoelectric conversion elements may include wire grid polarization elements. While a photoelectric conversion element unit is composed of a plurality of photoelectric conversion elements and a photoelectric conversion element group is composed of a plurality of photoelectric conversion element units, the photoelectric conversion element unit may have a Bayer arrangement, for example, and one photoelectric conversion element group (one pixel) may be composed of four photoelectric conversion element units (four subpixels). However, the arrangement of the photoelectric conversion element unit is not limited to the Bayer arrangement, and an interline arrangement, a G-stripe RB-check arrangement, a G-stripe RB-full check arrangement, a check complementary color arrangement, a stripe arrangement, a slanting stripe arrangement, a primary color chrominance arrangement, a field chrominance sequential arrangement, a frame chrominance sequential arrangement, a MOS type arrangement, an improved MOS type arrangement, a frame interleaving arrangement, and a field interleaving arrangement may be conceived. As described above, when color separation or light separation is not a purpose or in photoelectric conversion elements having sensitivity to a specific wavelength, the color filter layer may be unnecessary. Photoelectric conversion elements may include a combination of a photoelectric conversion element for red light which has sensitivity to red light, a photoelectric conversion element for green light which has sensitivity to green light, and a photoelectric conversion element for blue light which has sensitivity to blue light, or may include a combination of an infrared photoelectric conversion element having sensitivity to infrared rays in addition thereto. In the latter case, a configuration in which the infrared photoelectric conversion element having sensitivity to infrared rays includes a color filter layer that does not transmit lights in the first wavelength range, the second wavelength range, and the third wavelength range may be employed. In addition, the light receiving device and the like of the present disclosure may implement a solid-state imaging device for acquiring a monochrome image or a solid-state imaging device for acquiring a combination of a monochrome image and an image based on infrared rays.

In a case where the light receiving device and the like of the present disclosure is applied to a solid-state imaging device, as a photoelectric conversion element, a CCD element, a CMOS image sensor, a contact image sensor (CIS), or a charge modulation device (CMD) type signal amplification type image sensor may be conceived. The photoelectric conversion element is a surface irradiation type or back-side irradiation type photoelectric conversion element. For example, a digital still camera or a video camera, a camcorder, a monitoring camera, a vehicle-mounted camera, a smartphone camera, a user interface camera for games, and a biometric authentication camera may be configured using a solid-state imaging device. In addition, the light receiving device and the like of the present disclosure may implement a solid-state imaging device capable of simultaneously acquiring polarization information in addition to conventional imaging. Further, the light receiving device and the like of the present disclosure may implement a solid-state imaging device for capturing stereoscopic images. In a case where a solid-state imaging device is configured using the light receiving device and the like of the present disclosure, a single plate type color solid-state imaging device may be configured according to the solid-state imaging device.

### Embodiment 1

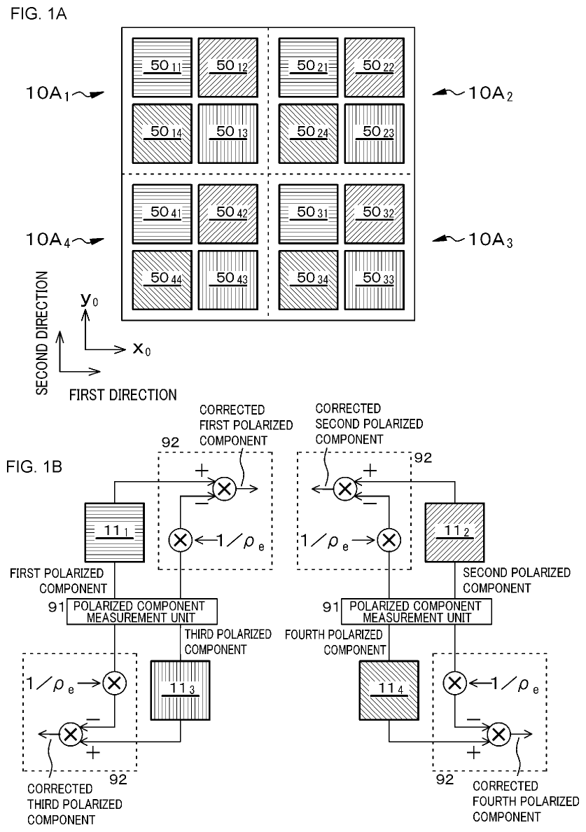

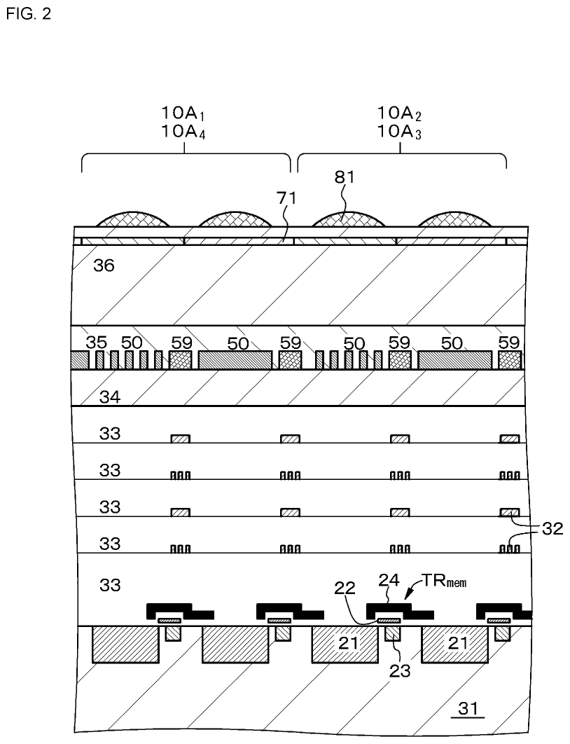

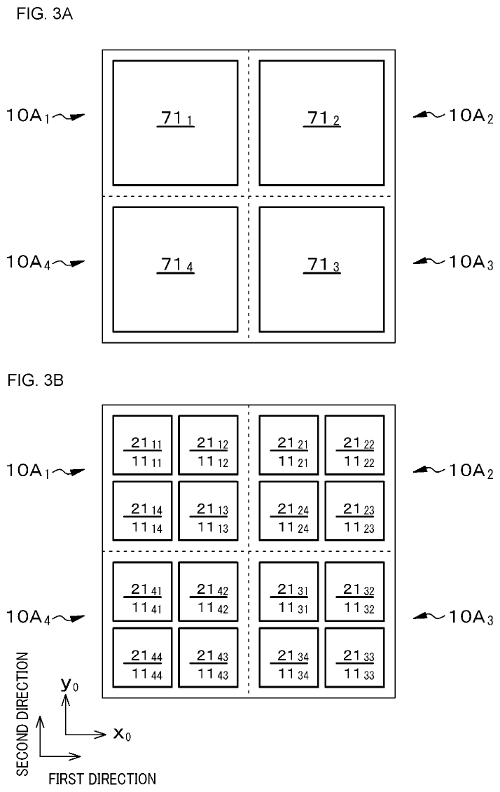

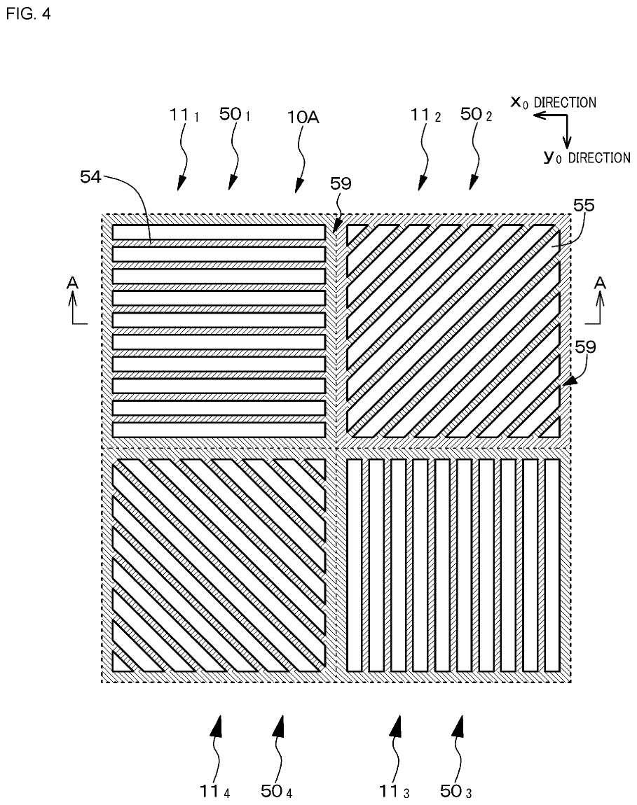

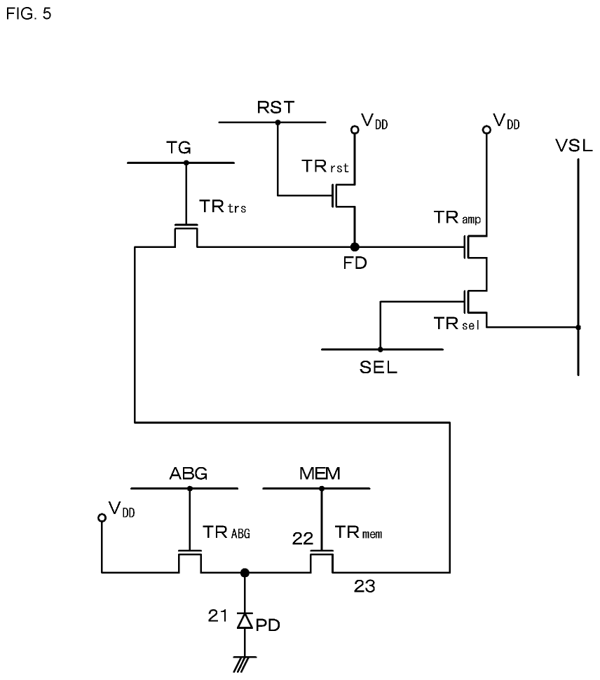

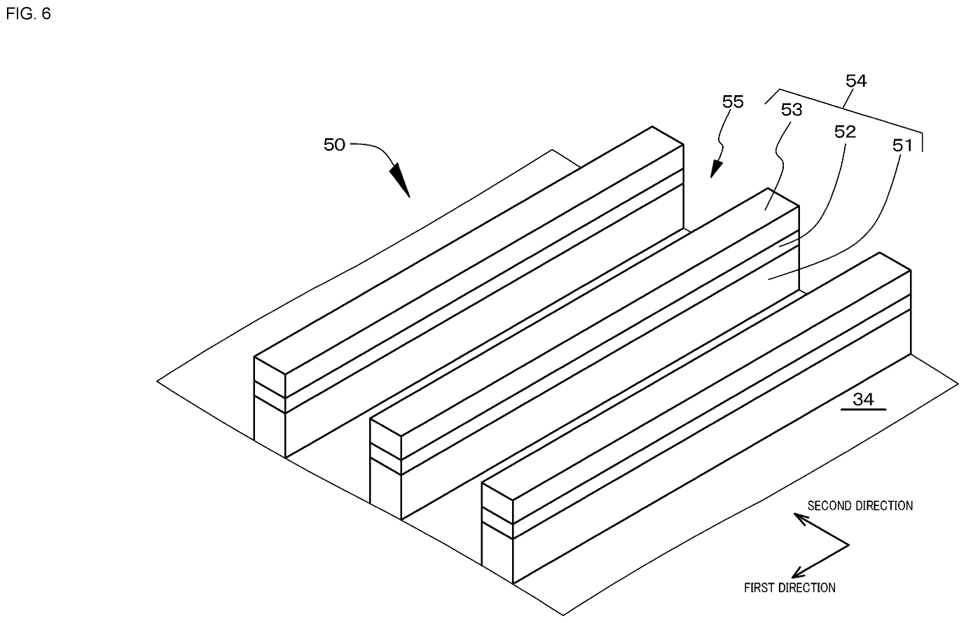

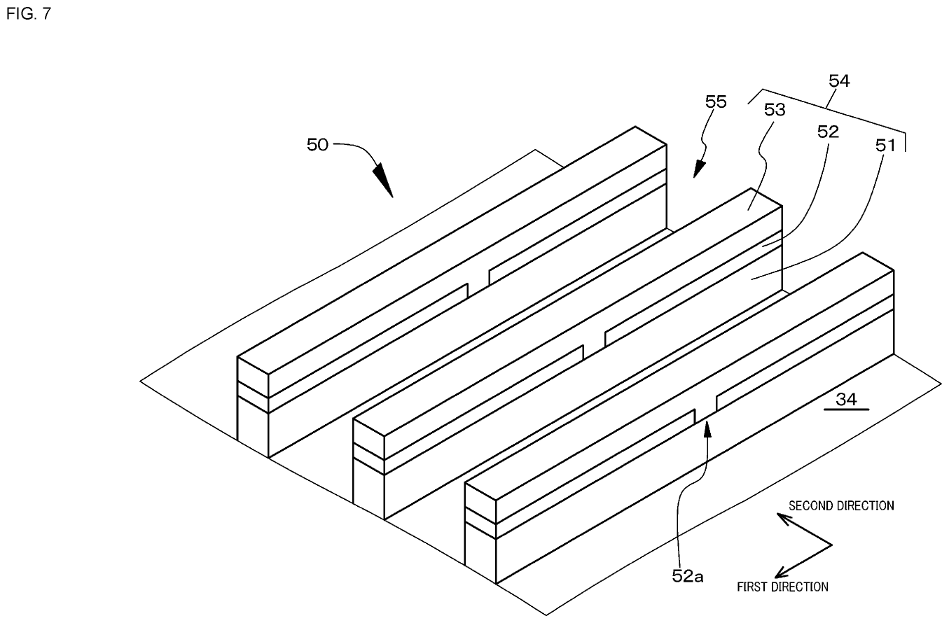

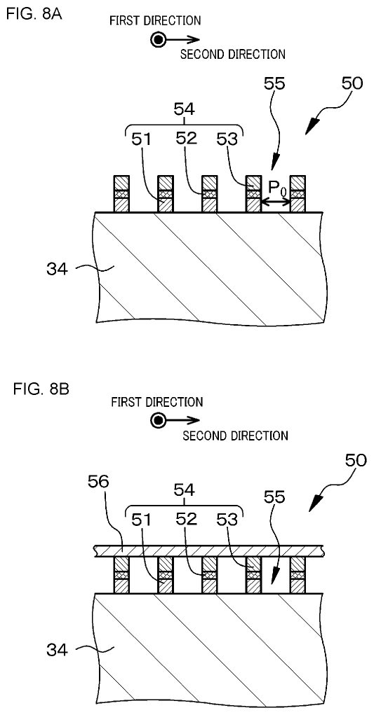

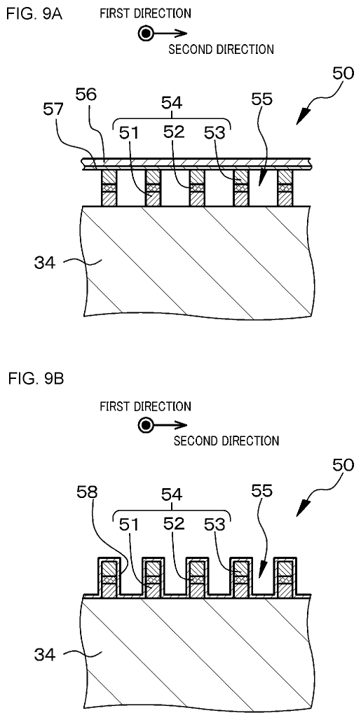

Embodiment 1 pertains to a light receiving device according to the second aspect of the present disclosure. A schematic plan view of wire grid polarization elements constituting photoelectric conversion elements of 2×2=4 photoelectric conversion element units in the light receiving device of embodiment 1 is illustrated in FIG. 1A, a method of calculating a first polarized component and a second polarized component is illustrated in FIG. 1B, a schematic partial cross-sectional view of the light receiving device of embodiment 1, taken along arrow A-A of FIG. 4A is illustrated in FIG. 2, and a conceptual plan view of a color filter layer constituting photoelectric conversion elements of the light receiving device of embodiment 1 and a conceptual plan view of photoelectric conversion parts (light receiving parts and imaging parts) are illustrated in FIG. 3A and FIG. 3B. In addition, a schematic plan view of wire grid polarization elements constituting photoelectric conversion elements of the light receiving device of embodiment 1 is illustrated in FIG. 4, and an equivalent circuit diagram of a photoelectric conversion part in the light receiving device (solid-state imaging device) of embodiment 1 is illustrated in FIG. 5. Further, schematic perspective views of wire grid polarization elements are illustrated in FIG. 6 and FIG. 7, and schematic partial cross-sectional views of wire grid polarization elements are illustrated in FIG. 8A, FIG. 8B, FIG. 9A, and FIG. 9B.

The light receiving device of embodiment 1 includes

a plurality of photoelectric conversion element units 10A₁, 10A₂, 10A₃, and 10A₄ composed of

a first photoelectric conversion element 11ⱼ₁ including a first polarization element 50ⱼ₁,

a second photoelectric conversion element 11ⱼ₂ including a second polarization element 50ⱼ₂,

a third photoelectric conversion element 11ⱼ₃ including a third polarization element 50ⱼ₃, and

a fourth photoelectric conversion element 11ⱼ₄ including a fourth polarization element 50ⱼ₄, and

further includes a polarized component measurement unit 91 and a polarized component calculation unit 92.

A reciprocal (1/ρₑ) of an extinction ratio is stored in the polarized component calculation unit 92.

In addition, the first polarization element 50ⱼ₁ has a first polarization azimuth of an angle of α degrees,

the second polarization element 50ⱼ₂ has a second polarization azimuth of an angle of (α+45) degrees,

the third polarization element 50ⱼ₃ has a third polarization azimuth of an angle of (α+90) degrees, and

the fourth polarization element 50ⱼ₄ has a fourth polarization azimuth of an angle of (α+135) degrees.

Here, j is any of 1, 2, 3, and 4, and when j=1, for example, the polarization elements 50ⱼ₁, 50ⱼ₂, 50ⱼ₃, and 50ⱼ₄ represent polarization elements 50₁₁, 50₁₂, 50₁₃, and 50₁₄. The same applies to description of other components in photoelectric conversion elements and photoelectric conversion parts.

Although an angle between a and the second direction may be inherently any angle, it is assumed to be 0 degrees in embodiment 1 and various embodiments which will be described later. In addition, it is assumed that the second direction is parallel to the y₀ direction. However, they are not limited thereto.

In addition, the plurality of photoelectric conversion elements 11ⱼ₁, 11ⱼ₂, 11ⱼ₃, and 11ⱼ₄ are arranged in a two-dimensional matrix form in the x₀ direction and the yo direction,

each of the photoelectric conversion element units 10A₁, 10A₂, 10A₃, and 10A₄ includes a single first photoelectric conversion element 11ⱼ₁, a single second photoelectric conversion element 11ⱼ₂, a single third photoelectric conversion element 11ⱼ₃, and a single fourth photoelectric conversion element 11ⱼ₄,

the first photoelectric conversion element 11ⱼ₁ and the second photoelectric conversion element 11ⱼ₂ are arranged in the x₀ direction (specifically, arranged adjacently),

the third photoelectric conversion element 11ⱼ₃ and the fourth photoelectric conversion element 11ⱼ₄ are arranged adjacently in the x₀ direction (specifically, arranged adjacently),

the first photoelectric conversion element 11ⱼ₁ and the fourth photoelectric conversion element 11ⱼ₄ are arranged in the y₀ direction (specifically, arranged adjacently), and

the second photoelectric conversion element 11ⱼ₂ and the third photoelectric conversion element 11ⱼ₃ are arranged in the y₀ direction (specifically, arranged adjacently).

A single photoelectric conversion element group is composed of the four photoelectric conversion element units 10A₁, 10A₂, 10A₃, and 10A₄. In addition, the photoelectric conversion element units 10A₁, 10A₂, 10A₃, and 10A₄ or photoelectric conversion element groups are arranged in a two-dimensional matrix form in the x₀ direction and the y₀ direction.

Photoelectric conversion elements are arranged in a 2×2 state, and in such an arrangement, polarized light transmission directions in two photoelectric conversion elements which neighbor in a diagonal direction are orthogonal to each other in any photoelectric conversion element. That is, light that transmits a certain photoelectric conversion element to the maximum is basically blocked by a polarization element in a photoelectric conversion element neighboring the certain photoelectric conversion element in a diagonal direction.

In light receiving devices of embodiment 1 or embodiments 2 and 3 which will be described later, the polarization elements 50ⱼ₁, 50ⱼ₂, 50ⱼ₃, and 50ⱼ₄ are composed of wire grid polarization elements. Here, it is desirable that a light transmissivity of a wire grid polarization element in a light transmission axis be equal to or greater than 80%. In addition, as an extinction ratio of the wire grid polarization element or an extinction ratio as a photoelectric conversion element, 10 or more and 1000 or less may be conceived. In particular, in a wavelength range of visible light wavelengths (425 to 725 nm), 50 or more and 500 or less may be conceived.

As illustrated on the left-hand side of FIG. 1B, the polarized component measurement unit 91 obtains a first polarized component of incident light on the basis of an output signal from the first photoelectric conversion element 11₁ and obtains a third polarized component of the incident light on the basis of an output signal from the third photoelectric conversion element 11₃. Then, the polarized component calculation unit 92 calculates a polarized component of the third polarization azimuth in the obtained first polarized component on the basis of the obtained third polarized component and calculates a polarized component of the first polarization azimuth in the obtained third polarized component on the basis of the obtained first polarized component.

However, an output signal OP₁ from the first photoelectric conversion element 11₁ includes not only the first polarized component OP₁₋₁ as a main component that is a polarization transmitting component but also the third polarized component OP₁₋₃ that is a polarization blocking component.

OP₁=OP¹⁻¹+OP₁₋₃

Here,

ρₑ=OP₁₋₁/OP₁₋₃ (1-1)

Accordingly,

OP₁₋₁=OP₁−OP₁₋₃ (1-2)

However, OP₁₋₃ in formula (1-2) is a value that cannot be directly obtained. Accordingly, in conventional technologies, a corrected first polarized component OP₁₋₁′ (the first polarized component OP₁₋₁′ from which the third polarized component OP₁₋₃ has been removed) is obtained on the basis of formula (1-1) through the following approximation.

OP₁₋₁′=OP₁1−OP₁1/ρₑ (1-3)

That is, the third polarized component OP₁₋₃ of the second term of the right side of formula (1-2) which is a polarization blocking component in the first photoelectric conversion element 11₁ is not a directly obtained value and the first polarized component OP₁₋₁′ is obtained on the assumption that OP₁=OP₁₋₃.

However, a photoelectric conversion element formation pitch in a general light receiving device is about several p.m, and thus any problem does not occur even if it is assumed that polarized components have continuity. Accordingly, in the light receiving device of embodiment 1, the first polarized component OP₁₋₁′ is obtained on the basis of an output signal OP₃ from the third photoelectric conversion element 11₃ through the following formula.

OP₁₋₁′=OP₁−OP₃/ρₑ (1-4)

Here, the output signal OP₃ from the third photoelectric conversion element 11₃ is an output signal based on light in a polarized state parallel to a light absorption axis in the first photoelectric conversion element 11₁ (a polarized state parallel to a light transmission axis in the third photoelectric conversion element 11₃). In addition, the third photoelectric conversion element 11₃ is composed of a photoelectric conversion element having high sensitivity, that is, capable of obtaining a high output signal, like the first photoelectric conversion element 11₁. Accordingly, the value of the second term of the right side of formula (1-4) has higher accuracy than the value of the second term of the right side of formula (1-3). In other words, it is possible to obtain a corrected polarized component having higher accuracy than conventional technologies.

As described above, the polarized component calculation unit 92 calculates the corrected first polarized component by subtracting a value obtained by multiplying the obtained value of the polarized component of the third polarization azimuth by the reciprocal 1/ρₑ of the extinction ratio from the obtained value of the first polarized component. Likewise, the polarized component calculation unit 92 calculates the corrected third polarized component by subtracting a value obtained by multiplying the obtained value of the polarized component of the first polarization azimuth by the reciprocal 1/ρₑ of the extinction ratio from the obtained value of the third polarized component.

In addition, as illustrated in the right-hand side of FIG. 1B, the polarized component measurement unit 91 obtains a second polarized component of the incident light on the basis of an output signal from the second photoelectric conversion element 11₂ and obtains a fourth polarized component of the incident light on the basis of an output signal from the fourth photoelectric conversion element 11₄. Then, the polarized component calculation unit 92 calculates a polarized component of the fourth polarization azimuth in the obtained second polarized component on the basis of the obtained fourth polarized component and calculates a polarized component of the second polarization azimuth in the obtained fourth polarized component on the basis of the obtained second polarized component. Specifically, the polarized component calculation unit 92 calculates a corrected second polarized component by subtracting a value obtained by multiplying the obtained value of the polarized component of the fourth polarization azimuth by the reciprocal 1/ρₑ of the extinction ratio from the obtained value of the second polarized component. In addition, the polarized component calculation unit 92 calculates a corrected fourth polarized component by subtracting a value obtained by multiplying the obtained value of the polarized component of the second polarization azimuth by the reciprocal 1/ρₑ of the extinction ratio from the obtained value of the fourth polarized component.

In the light receiving device of embodiment 1, a wire grid polarization element 50 and a photoelectric conversion part 21 are sequentially disposed from a light incident side in each photoelectric conversion element 11 constituting each photoelectric conversion element unit 10A. In addition, the photoelectric conversion part 21 having a known configuration and structure is formed in a silicon semiconductor substrate 31 through a known method. The photoelectric conversion part 21 is covered with a lower interlayer insulating layer 33, an underlying insulating layer 34 is formed on the lower interlayer insulating layer 33, and the wire grid polarization element 50 is formed on the underlying insulating layer 34. The wire grid polarization element 50 and the underlying insulating layer 34 are covered with a planarization film 35. An upper interlayer insulating layer 36 is formed on the planarization film 35 and on-chip microlenses 81 are arranged on the upper interlayer insulating layer 36. Meanwhile, arrangement of the on-chip microlenses 81 is not required. In addition, although five layers of the lower interlayer insulating layer 33 and four layers of wiring layer 32 are shown in the illustrated example, the present disclosure is not limited thereto and the numbers of layers of the lower interlayer insulating layer 33 and the wiring layer 32 are arbitrary.

Further, the light receiving device of embodiment 1 is composed of a plurality of photoelectric conversion element groups arranged in a two-dimensional form,

a single photoelectric conversion element group is composed of four photoelectric conversion element units 10A₁, 10A₂, 10A₃, and 10A₄ arranged in 2×2,

the first photoelectric conversion element unit 10A₁ includes a first color filter layer 71₁ that transmits light in a first wavelength range,

the second photoelectric conversion element unit 10A₂ includes a second color filter layer 71₂ that transmits light in a second wavelength range,

a third photoelectric conversion element unit 10A₃ includes a third color filter layer 71₃ that transmits light in a third wavelength range, and

a fourth photoelectric conversion element unit 10A₄ includes a fourth color filter layer 71₄ that transmits light in a fourth wavelength range.

Specifically, a single photoelectric conversion element group may be, for example, composed of the four photoelectric conversion element units 10A₁, 10A₂, 10A₃, and 10A₄. Red light as light in the first wavelength range, green light as light in the second wavelength range and the third wavelength range, and blue light as light in the fourth wavelength range may be conceived.

The first photoelectric conversion element unit 10A₁ is composed of four first photoelectric conversion elements 11₁₁, 11₁₂, 11₁₃, and 11₁₄. The first photoelectric conversion element 11₁₁ is composed of the on-chip microlenses 81, the first color filter layer 71₁, a wire grid polarization element 50₁₁, and a photoelectric conversion part 21₁₁ from an incident light side. In addition, the second photoelectric conversion element 11₁₂ is composed of the on-chip microlenses 81, the first color filter layer 71₁, a wire grid polarization element 50₁₂, and a photoelectric conversion part 21₁₂ from the incident light side. Further, the third photoelectric conversion element 11₁₃ is composed of the on-chip microlenses 81, the first color filter layer 71₁, a wire grid polarization element 50₁₃, and a photoelectric conversion part 21₁₃ from the incident light side. Further, the fourth photoelectric conversion element 11₁₄ is composed of the on-chip microlenses 81, the first color filter layer 71₁, a wire grid polarization element 50₁₄, and a photoelectric conversion part 21₁₄ from the incident light side.

The second photoelectric conversion element unit 10A₂ is composed of four first photoelectric conversion elements 11₂₁, 11₂₂, 11₂₃, and 11₂₄. The second photoelectric conversion element 11₂₁ is composed of the on-chip microlenses 81, the second color filter layer 71₂, a wire grid polarization element 50₂₁, and a photoelectric conversion part 21₂₁ from the incident light side. In addition, the second photoelectric conversion element 11₂₂ is composed of the on-chip microlenses 81, the second color filter layer 71₂, a wire grid polarization element 50₂₂, and a photoelectric conversion part 21₂₂ from the incident light side. Further, the third photoelectric conversion element 11₂₃ is composed of the on-chip microlenses 81, the second color filter layer 71₂, a wire grid polarization element 50₂₃, and a photoelectric conversion part 21₂₃ from the incident light side. Further, the fourth photoelectric conversion element 11₂₄ is composed of the on-chip microlenses 81, the second color filter layer 71₂, a wire grid polarization element 50₂₄, and a photoelectric conversion part 21₂₄ from the incident light side.

The third photoelectric conversion element unit 10A₃ is composed of four first photoelectric conversion elements 11₃₁, 11₃₂, 11₃₃, and 11₃₄. The third photoelectric conversion element 11₃₁ is composed of the on-chip microlenses 81, the third color filter layer 71₃, a wire grid polarization element 50₃₁, and a photoelectric conversion part 21₃₁ from the incident light side. In addition, the third photoelectric conversion element 11₃₂ is composed of the on-chip microlenses 81, the third color filter layer 71₃, a wire grid polarization element 50₃₂, and a photoelectric conversion part 21₃₂ from the incident light side. Further, the third photoelectric conversion element 11₃₃ is composed of the on-chip microlenses 81, the third color filter layer 71₃, a wire grid polarization element 50₃₃, and a photoelectric conversion part 21₃₃ from the incident light side. Further, the fourth photoelectric conversion element 11₃₄ is composed of the on-chip microlenses 81, the third color filter layer 71₃, a wire grid polarization element 50₃₄, and a photoelectric conversion part 21₃₄ from the incident light side.

The fourth photoelectric conversion element unit 10A₄ is composed of four first photoelectric conversion elements 11₄₁, 11₄₂, 11₄₃, and 11₄₄. The fourth photoelectric conversion element 11₄₁ is composed of the on-chip microlenses 81, the fourth color filter layer 71₄, a wire grid polarization element 50₄₁, and a photoelectric conversion part 21₄₁ from the incident light side. In addition, the fourth photoelectric conversion element 11₄₂ is composed of the on-chip microlenses 81, the fourth color filter layer 71₄, a wire grid polarization element 50₄₂, and a photoelectric conversion part 21₄₂ from the incident light side. Further, the fourth photoelectric conversion element 11₄₃ is composed of the on-chip microlenses 81, the fourth color filter layer 71₄, a wire grid polarization element 50₄₃, and a photoelectric conversion part 21₄₃ from the incident light side. Further, the fourth photoelectric conversion element 11₄₄ is composed of the on-chip microlenses 81, the fourth color filter layer 71₄, a wire grid polarization element 50₄₄, and a photoelectric conversion part 21₄₄ from the incident light side.

The photoelectric conversion part 21 having a known configuration and structure is formed in the silicon semiconductor substrate 31 through a known method. In addition, a memory TRₘₑₘ that is connected to the photoelectric conversion part 21 and temporarily stores charges generated in the photoelectric conversion part 21 is formed on the semiconductor substrate 31.

The memory TRₘₑₘ is composed of the photoelectric conversion part 21, a gate 22, a channel formation region, and a high-concentration impurity region 23. The gate 22 is connected to a memory selection line MEM. In addition, the high-concentration impurity region 23 is formed in the silicon semiconductor substrate 31 separately from the photoelectric conversion part 21 through a known method. A light shielding film 24 is formed above the high-concentration impurity region 23. That is, the high-concentration impurity region 23 is covered with the light shielding film 24. Accordingly, light incident on the high-concentration impurity region 23 is blocked. It is possible to easily realize a so-called global shutter function by including the memory TRₘₑₘ that temporarily stores charges. As a material forming the light shielding film 24, chrome (Cr), copper (Cu), aluminum (Al), tungsten (W), and a resin through which light cannot pass (e.g., polyimide resin) may be exemplified.

A transfer transistor TRₜᵣₛ illustrated only in FIG. 5 is composed of a gate connected to a transfer gate line TG, a channel formation region, one source/drain region connected to the high-concentration impurity region 23 (or sharing the region with the high-concentration impurity region 23), and the other source/drain region constituting a floating diffusion layer FD.

A reset transistor TRᵣₛₜ illustrated only in FIG. 5 is composed of a gate, a channel formation region, and source/drain regions. The gate of the reset transistor TRᵣₛₜ is connected to a reset line RST, one source/drain of the reset transistor TRᵣₛₜ is connected to a power source V_{DD}, and the other source/drain region also serves as the floating diffusion layer FD.

An amplification transistor TRₐₘₚ illustrated only in FIG. 5 is composed of a gate, a channel formation region, and source/drain regions. The gate is connected to the other source/drain region (floating diffusion layer FD) of the reset transistor TRᵣₛₜ via a wiring layer. In addition, one source/drain region is connected to the power source V_{DD}.

A select transistor TRₛₑₗ illustrated only in FIG. 5 is composed of a gate, a channel formation region, and source/drain regions. The gate is connected to a select line SEL. In addition, one source/drain region shares the region with the other source/drain region constituting the amplification transistor TRₐₘₚ and the other source/drain region is connected to a signal line (data output line) VSL (117).

Further, the photoelectric conversion part 21 is connected to one source/drain region of a charge discharge control transistor TR_{ABG}. A gate of the charge discharge control transistor TR_{ABG} is connected to a charge discharge control transistor control line ABG and the other source/drain region is connected to the power source V_{DD}.

A series of operations of the photoelectric conversion part 21, such as charge accumulation, a reset operation, and charge transfer, is the same as a series of operations such as charge accumulation, a reset operation, and charge transfer in a conventional photoelectric conversion part, and thus detailed description thereof is omitted.

The photoelectric conversion part 21, the memory TRₘₑₘ, the transfer transistor TRₜᵣₛ, the reset transistor TRᵣₛₜ, the amplification transistor TRₐₘₚ, the select transistor TRₛₑₗ, and the charge discharge control transistor TR_{ABG} are covered with the lower interlayer insulating layer 33.

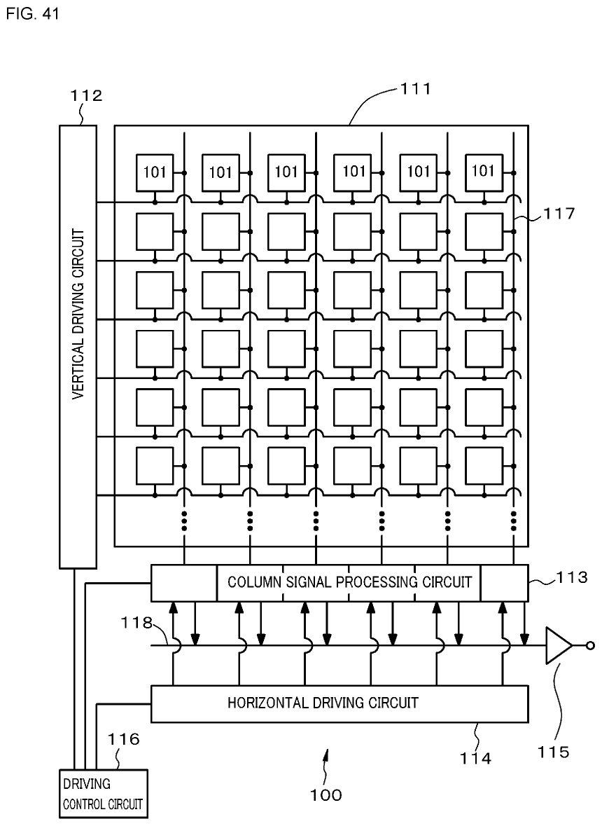

FIG. 41 illustrates a conceptual diagram of a solid-state imaging device when the light receiving device of embodiment 1 is applied to the solid-state imaging device. A solid-state imaging device 100 of embodiment 1 is composed of an imaging area (effective pixel area) 111 in which a photoelectric conversion parts 101 are arranged in a two-dimensional array form, and a vertical driving circuit 112, a column signal processing circuit 113, a horizontal driving circuit 114, an output circuit 115, a driving control circuit 116, and the like which are arranged in a peripheral area and serve as driving circuits (peripheral circuits) thereof. These circuits may be configured as known circuits or configured using other circuit configurations (e.g., various circuits used for a conventional CCD type solid-state imaging device and CMOS type solid-state imaging device). In FIG. 41, a reference numeral “101” in the photoelectric conversion parts 101 is displayed only in the first row.

The driving control circuit 116 generates a clock signal and a control signal that are references for operations of the vertical driving circuit 112, the column signal processing circuit 113, and the horizontal driving circuit 114 on the basis of a vertical synchronization signal, a horizontal synchronization signal, and a master clock signal. Then, the generated clock signal and control signal are input to the vertical driving circuit 112, the column signal processing circuit 113, and the horizontal driving circuit 114.

The vertical driving circuit 112 may be configured as a shift register, for example, and sequentially selectively scans the photoelectric conversion parts 101 of the imaging area 111 in units of row in the vertical direction. In addition, a pixel signal (image signal) based on a current (signal) generated in response to an amount of received light in each photoelectric conversion part 101 is transmitted to the column signal processing circuit 113 through signal lines (data output lines) 117 and VSL.

The column signal processing circuit 113 is arranged, for example, for each column of the photoelectric conversion parts 101 and performs signal processing for noise removal or signal amplification on an image signal output from photoelectric conversion parts 101 corresponding to one row according to a signal from black reference pixels (formed around the effective pixel area although not illustrated) for each photoelectric conversion part. A horizontal select switch (not illustrated) is connected to an output stage of the column signal processing circuit 113 between the output stage and a horizontal signal line 118.

The horizontal driving circuit 114 is configured as a shift register, for example, sequentially selects respective column signal processing circuits 113 by sequentially outputting horizontal scan pulses and outputs signals from the respective column signal processing circuits 113 to the horizontal signal line 118.

The output circuit 115 performs signal processing on signals sequentially supplied from the respective column signal processing circuits 113 through the horizontal signal line 118 and outputs the processed signals.

As illustrated in FIG. 6 and FIG. 8A, the wire grid polarization element 50 has a line-and-space structure. A line part 54 of the wire grid polarization element 50 is composed of a laminated structure (first laminated structure) in which a light reflection layer 51 formed of a first conductive material (specifically, aluminum (Al)), an insulating film 52 formed of SiO₂, and a light absorption layer 53 formed of a second conductive material (specifically, tungsten (W)) are laminated from an opposite side of the light incident side (the photoelectric conversion part side in embodiment 1). The insulating film 52 is formed on the overall top face of the light reflection layer 51 and the light absorption layer 53 is formed on the overall top surface of the insulating film 52. Specifically, the light reflection layer 51 is formed of aluminum (Al) to a thickness of 150 nm, the insulating film 52 is formed of SiO₂ to a thickness of 25 nm or 50 nm, and the light absorption layer 53 is formed of tungsten (W) to a thickness of 25 nm. The light reflection layer 51 has a function as a polarizer, attenuates polarized waves having an electric field component in a direction parallel to a direction (first direction) in which the light reflection layer 51 extends in light incident on the wire grid polarization element 50, and transmits polarized waves having an electric field component in a direction (second direction) orthogonal to the direction in which the light reflection layer 51 extends. The first direction is a light absorption axis of the wire grid polarization element 50 and the second direction is a light transmission axis of the wire grid polarization element 50. While an underlying film formed of Ti, TiN, or a laminated structure of Ti/TiN is formed between the underlying insulating layer 34 and the light reflection layer 51, illustration of the underlying film is omitted.

The light reflection layer 51, the insulating film 52, and the light absorption layer 53 are common in the photoelectric conversion elements 11. A frame part 59 is configured using a laminated structure (second laminated structure) composed of the light reflection layer 51, the insulating film 52, and the light absorption layer 53 except that a space part 55 is not provided therein. That is, as illustrated in the schematic plan view of FIG. 4, the frame part 59 surrounding the wire grid polarization element 50 is provided and the frame part 59 and the line part 54 of the wire grid polarization element 50 are connected. In this manner, the frame part 59 has the same structure as the line part 54 of the wire grid polarization element 50 and also serves as a light shielding part.

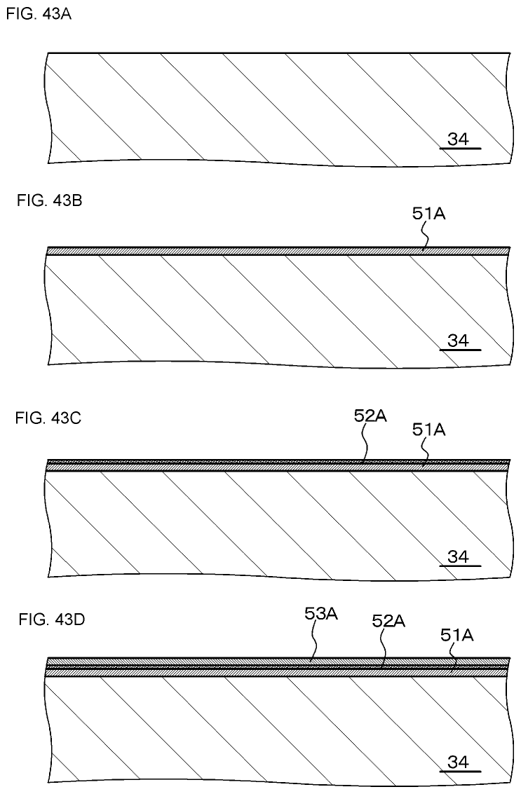

The wire grid polarization element 50 may be manufactured through the following method. That is, an underlying film (not shown) formed of Ti, TiN, or a laminated structure of Ti/TiN and a light reflection layer formation layer 51A formed of the first conductive material (specifically, aluminum) are provided on the underlying insulating layer 34 on the basis of the vacuum evaporation method (refer to FIG. 43A and FIG. 43B). Subsequently, an insulating film formation layer 52A is provided on the light reflection layer formation layer 51A, and a light absorption layer formation layer 53A formed of the second conductive material is provided on the insulating film formation layer 52A. Specifically, the insulating film formation layer 52A is formed of SiO₂ on the light reflection layer formation layer 51A on the basis of a CVD method (refer to FIG. 43C). Then, the light absorption layer formation layer 53A is formed of tungsten (W) on the insulating film formation layer 52A through a sputtering method. In this manner, the structure illustrated in FIG. 43D can be obtained.

Thereafter, the wire grid polarization element 50 having a line-and-space structure in which a plurality of line parts (laminated structures) 54 each including the band-shaped light reflection layer 51, the insulating film 52, and the light absorption layer 53 are spaced and arranged in parallel can be obtained by patterning the light absorption layer formation layer 53A, the insulating film formation layer 52A, the light reflection layer formation layer 51A, and the underlying film on the basis of a lithography technique and a dry etching technique. Thereafter, the planarization film 35 may be formed to cover the wire grid polarization element 50 on the basis of a CVD method. The wire grid polarization element 50 is surrounded by the frame part 59 (refer to FIG. 4) composed of the light reflection layer 51, the insulating film 52, and the light absorption layer 53.

As a modified example of the wire grid polarization element 50, a configuration in which a protective film 56 formed on the wire grid polarization element 50 is provided and the space parts 55 of the wire grid polarization element 50 are voids, as illustrated in a schematic partial cross-sectional view of FIG. 8B, may be conceived. That is, some or all space parts 55 are filled with the air. Specifically, all space parts 55 are filled with the air in embodiment 1.

In addition, as illustrated in a schematic partial cross-sectional view of FIG. 9A, a configuration in which a second protective film 57 is formed between the wire grid polarization element 50 and the protective film 56 may be conceived. When a refractive index of a material forming the protective film 56 is n₁′ and a refractive index of a material forming the second protective film 57 is n₂′, n₁′>n₂′ is satisfied. Here, the protective film 56 may be formed of SiN (n₁′=2.0) and the second protective film 57 may be formed of SiO₂ (n₂′=1.5), for example. Although the bottom face of the second protective film 57 (face opposite the underlying insulating layer 34) is represented as flat in the figure, there are cases in which the bottom face of the second protective film 57 is protruded toward the space parts 55, the bottom face of the second protective film 57 is recessed toward the protective film 56, or the bottom face of the second protective film 57 is recessed in a wedge shape.

This structure is obtained by forming the second protective film 57 of SiO₂ to an average thickness of 0.01 μm to 10 μm on the basis of a CVD method after acquisition of the wire grid polarization element 50 having the line-and-space structure. The top of the space part 55 positioned between lines parts 54 is closed with the second protective film 57. Subsequently, the protective film 56 is formed of SiN to an average thickness of 0.1 μm to 10 μm on the second protective film 57 on the basis of a CVD method. It is possible to obtain photoelectric conversion parts with high reliability by forming the protective film 56 using SiN. However, since SiN has a relatively high dielectric constant, reduction of the average refractive index nₐᵥₑ is promoted by forming the second protective film 57 using SiO₂.

In this manner, the spaces parts of the wire grid polarization elements are formed as voids (specifically, filled with the air), and thus the value of the average refractive index nₐᵥₑ can be reduced. Consequently, it is possible to promote improvement of transmissivity and optimization of an extinction ratio in the wire grid polarization elements. In addition, it is possible to promote improvement of manufacturing yield of the wire grid polarization elements because the value of the formation pitch P₀ can be increased. Furthermore, if the protective film is formed on the wire grid polarization elements, photoelectric conversion parts and a light receiving device having high reliability can be provided. In addition, it is possible to form stabilized and homogeneous and uniform wire grid polarization elements by connecting the frame part and line part of the wire grid polarization elements and forming the frame part in the same structure as the line parts of the wire grid polarization elements. Accordingly, it is possible to solve a problem that exfoliation occurs at circumferential parts of the wire grid polarization elements corresponding to four corners of photoelectric conversion parts, a problem that a difference between the structure of the circumferential parts of the wire grid polarization elements and the structure of the center parts of the wire grid polarization elements is generated to deteriorate the performance of the wire grid polarization elements, and a problem that light incident on the circumferential parts of the wire grid polarization elements easily leaks to neighboring photoelectric conversion parts in a different polarization direction, to provide photoelectric conversion parts and a light receiving device having high reliability.

The wire grid polarization elements may employ a structure in which an insulating film is omitted, that is, a configuration in which a light reflection layer (formed of aluminum, for example) and a light absorption layer (formed of tungsten, for example) are laminated from the opposite side of the light incident side. Alternatively, the wire grid polarization elements may be composed of one conductive light-shielding material layer. As a material forming the conductive light-shielding material layer, a conductive material having a low complex refractive index in a wavelength region in which photoelectric conversion parts have sensitivity, such as aluminum (Al), copper (Cu), gold (Au), silver (Ag), platinum (Pt), tungsten (W), or an alloy containing these metals may be conceived.

In some cases, as illustrated in a schematic partial cross-sectional view of the wire grid polarization element in FIG. 9B, a third protective film 58 formed of SiO₂ may be present on the side of line parts 54 facing the space parts 55, for example. That is, the space parts 55 are filled with the air and the third protective film 58 is additionally present on the space parts. The third protective film 58 may be formed, for example, on the basis of the HDP-CVD method, and thus the further thinner third protective film 58 can be conformally formed on the side of the line parts 54.

In some cases, as illustrated in a schematic perspective view of a modified example of a wire grid polarization element in FIG. 7, a configuration in which a part of the insulating film 52 is cut out and the light reflection layer 51 and the light absorption layer 53 come into contact with each other at the cut part 52a of the insulating film 52 may be conceived.

As described above, in the light receiving device of the embodiment, in photoelectric conversion elements A and B having two polarization elements A and B that pass exclusively polarized components having polarization directions orthogonal to each other, such as polarized components A and B, the whole polarized component A is obtained by the photoelectric conversion element A and the whole polarized component B is obtained by the photoelectric conversion element B. In addition, corrected polarized components A′ and B′ can be obtained on the basis of the polarized components A and B and a reciprocal of an extinction ratio obtained in advance. Accordingly, it is possible to obtain a polarized component having high correction accuracy from which unnecessary polarized components (polarized components that should be absorbed by wire grid polarization elements) have been removed, for example, using photoelectric conversion elements having high sensitivity in which the wire grid polarization element formation pitch P₀ has extended.

Furthermore, in calculation of a polarized component in the light receiving device of the present disclosure, there are advantages that the same calculation formulas can be applied basically even when target photoelectric conversion elements are changed due to the property that any target photoelectric conversion elements have an orthogonal relationship therebetween with respect to the polarization state. Moreover, there is a considerable merit in implementation because a series of processes such as correction and calculation of polarized components can be configured through pipeline processing using the same circuit configuration. Meanwhile, although cases in which an orthogonal relationship with respect to the polarization state has been broken down may also be conceived, formula (1-3) may be modified into a format of calculating a shielding component orthogonal to a transmitting component in a target photoelectric conversion element by weighting angle information, and the like.

It is possible to actively mitigate trade-off of an extinction ratio and sensitivity characteristic in design of actual polarization elements (wire grid) by using the technology of the light receiving device of the present disclosure. In the above-described technology disclosed in JP H09-090129A, a wavelength width in which light transmissivity of a light absorption axis (S-polarized component transmissivity) is less than 2% (40 or higher in conversion into an extinction ratio) is not present in a region in which light transmissivity of a light transmission axis (P-polarized component transmissivity) exceeds 80% (the region in which the value of b/d is less than 0.48). This means that it is difficult to manufacture a polarization element having a practical wavelength width having an extinction ratio exceeding 40 when the light transmissivity of the light transmission axis exceeds 80%. According to the light receiving device of the present disclosure, by performing correction of about 75% on the second term of the right side of formula (1-3), for example, the extinction ratio can be improved about four times compared to a case in which the correction has not been performed. Accordingly, it is possible to obtain about 100 as an extinction ratio in a region having a light transmissivity of 80%, for example. This characteristic is particularly suitable for shape recognition for FA, ITS, monitoring, and the like which particularly require sensitivity

Furthermore, in the light receiving device of embodiment 1, a polarization separation function of spatially polarization-separating polarization information of incident light may be provided to the light receiving device (solid-state imaging device). Specifically, it is possible to obtain light intensity, polarized component intensity, and a polarization direction in each photoelectric conversion element (imaging element). For example, it is possible to emphasize or reduce a polarized component or separate various polarized components by applying desired processing to a part of a captured image of the sky or window glass, a part of a captured image of the surface of the water, or the like, to improve the contrast of images and delete unnecessary information.

In some cases, in the light receiving device of embodiment 1 or embodiment 2 which will be described later, the color filter layer 71 may be omitted, and a light receiving device having this configuration may be applied to a light receiving device (e.g., a sensor) that does not aim color separation or light separation, for example, and a photoelectric conversion element itself has sensitivity to a specific wavelength.

### Embodiment 2

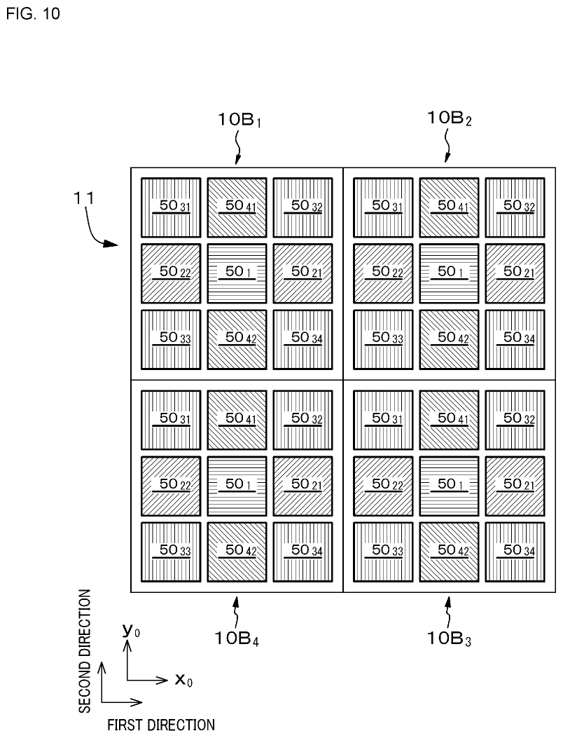

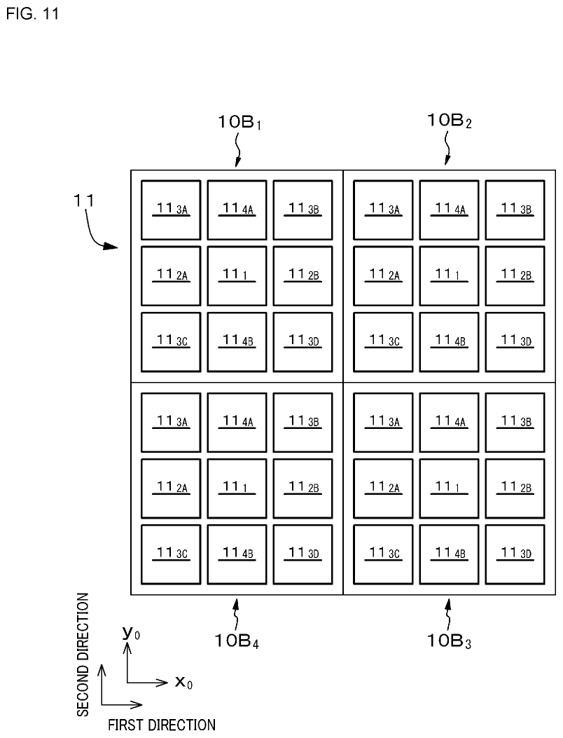

Embodiment 2 is a modification of embodiment 1. A schematic plan view of wire grid polarization elements constituting photoelectric conversion elements of four photoelectric conversion element units in the light receiving device of embodiment 2 is illustrated in FIG. 10, and a conceptual plan view of photoelectric conversion elements of the light receiving device of embodiment 2 is illustrated in FIG. 11. Meanwhile, four photoelectric conversion element units 10B₁, 10B₂, 10B₃, and 10B₄ constitute a single photoelectric conversion element group.

In addition, a plurality of photoelectric conversion elements are arranged in a two-dimensional matrix form in the x₀ direction and the y₀ direction,

each of the photoelectric conversion element units 10B₁, 10B₂, 10B₃, and 10B₄ includes: a single first photoelectric conversion element 11₁ (including a wire grid polarization element 50₁);

two second photoelectric conversion elements (including wire grid polarization elements 50₂₁ and 50₂₂) of a (2-A)-th photoelectric convention element 11_{2A} and a (2-B)-th photoelectric conversion element 11_{2B};

four third photoelectric conversion elements (including wire grid polarization elements 50₃₁, 50₃₂, 50₃₃, and 50₃₄) of a (3-A)-th photoelectric convention element 11_{3A}, a (3-B)-th photoelectric conversion element 11_{3B}, a (3-C)-th photoelectric convention element 11_{3C}, and a (3-D)-th photoelectric conversion element 11_{3D}; and

two fourth photoelectric conversion elements (including wire grid polarization element 50₄₁ and 50₄₂) of a (4-A)-th photoelectric convention element 11_{4A} and a (4-B)-th photoelectric conversion element 11_{4B}, the (3-A)-th photoelectric conversion element 11_{3A},

the (4-A)-th photoelectric conversion element 11_{4A}, and the (3-B)-th photoelectric conversion element 11_{3B} are arranged adjacently in the x₀ direction,

the (2-A)-th photoelectric conversion element 11_{2A}, the first photoelectric conversion element 11₁, and the (2-B)-th photoelectric conversion element 11_{2B} are arranged adjacently in the x₀ direction,

the (3-C)-th photoelectric conversion element 11_{3C}, the (4-B)-th photoelectric conversion element 11_{4B}, and the (3-D)-th photoelectric conversion element 11_{3D} are arranged adjacently in the x₀ direction,

the (3-A)-th photoelectric conversion element 11_{3A}, the (2-A)-th photoelectric conversion element 11_{2A}, and the (3-C)-th photoelectric conversion element 11_{3C} are arranged adjacently in the y₀ direction,

the (4-A)-th photoelectric conversion element 11_{4A}, the first photoelectric conversion element 11₁, and the (4-B)-th photoelectric conversion element 11_{4B} are arranged adjacently in the y₀ direction, and

the (3-B)-th photoelectric conversion element 11_{3B}, the (2-B)-th photoelectric conversion element 11_{2B}, and the (3-D)-th photoelectric conversion element 11_{3D} are arranged adjacently in the y₀ direction.

Except the aforementioned points, the configuration and the structure of the light receiving device of embodiment 2 may be the same as the configuration and the structure of the light receiving device described in embodiment 1.

However, in the light receiving device of embodiment 2,

the polarized component measurement unit 91

obtains a first polarized component of incident light on the basis of an output signal from the first photoelectric conversion element 11₁,

obtains a (2-A)-th polarized component of the incident light on the basis of an output signal from the (2-A)-th photoelectric conversion element 11_{2A},

obtains a (2-B)-th polarized component of the incident light on the basis of an output signal from the (2-B)-th photoelectric conversion element 11_{2B},

obtains a (3-A)-th polarized component of the incident light on the basis of an output signal from the (3-A)-th photoelectric conversion element 11_{3A},

obtains a (3-B)-th polarized component of the incident light on the basis of an output signal from the (3-B)-th photoelectric conversion element 11_{3B},

obtains a (3-C)-th polarized component of the incident light on the basis of an output signal from the (3-C)-th photoelectric conversion element 11_{3C},

obtains a (3-D)-th polarized component of the incident light on the basis of an output signal from the (3-D)-th photoelectric conversion element 11_{3D},

obtains a (4-A)-th polarized component of the incident light on the basis of an output signal from the (4-A)-th photoelectric conversion element 11_{4A}, and

obtains a (4-B)-th polarized component of the incident light on the basis of an output signal from the (4-B)-th photoelectric conversion element 11_{4B}.

In addition, the polarized component calculation unit 92

calculates a polarized component of a third polarization azimuth in the obtained first polarized component on the basis of an obtained third polarized component (the average of the (3-A)-th polarized component, the (3-B)-th polarized component, the (3-C)-th polarized component, and the (3-D)-th polarized component),

calculates a polarized component of a first polarization azimuth in the obtained third polarized component (the average of the (3-A)-th polarized component, the (3-B)-th polarized component, the (3-C)-th polarized component, and the (3-D)-th polarized component) on the basis of the obtained first polarized component,

calculates a polarized component of a fourth polarization azimuth in an obtained second polarized component (the average of the (2-A)-th polarized component and the (2-B)-th polarized component) on the basis of an obtained fourth polarized component (the average of the (4-A)-th polarized component and the (4-B)-th polarized component), and

calculates a polarized component of a second polarization azimuth in the obtained fourth polarized component (the average of the (4-A)-th polarized component and the (4-B)-th polarized component) on the basis of the obtained second polarized component (the average of the (2-A)-th polarized component and the (2-B)-th polarized component).

Specifically, the polarized component calculation unit 92

calculates a corrected first polarized component by subtracting a value obtained by multiplying an obtained value of the polarized component of the third polarization azimuth by a reciprocal of an extinction ratio from an obtained value of the first polarized component,

calculates a corrected third polarized component by subtracting a value obtained by multiplying an obtained value of the polarized component of the first polarization azimuth by the reciprocal of the extinction ratio from an obtained value of the third polarized component,

calculates a corrected second polarized component by subtracting a value obtained by multiplying an obtained value of the polarized component of the fourth polarization azimuth by the reciprocal of the extinction ratio from an obtained value of the second polarized component, and

calculates a corrected fourth polarized component by subtracting a value obtained by multiplying an obtained value of the polarized component of the second polarization azimuth by the reciprocal of the extinction ratio from an obtained value of the fourth polarized component.

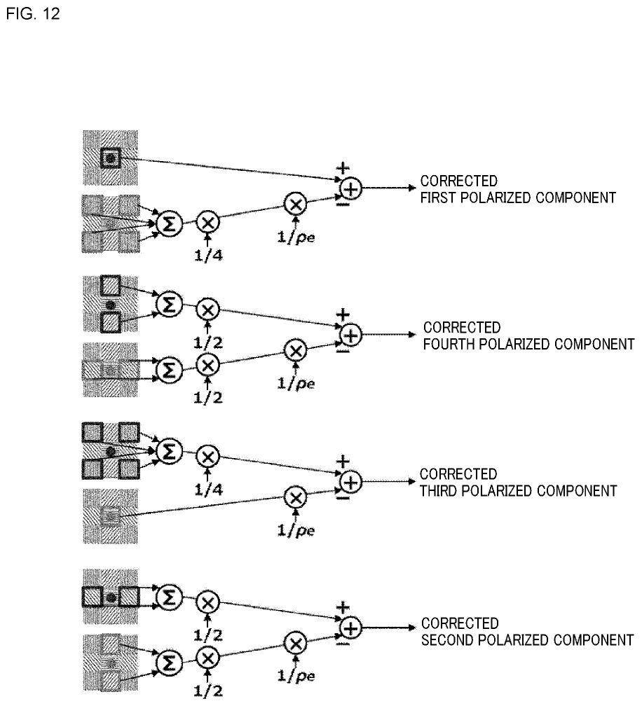

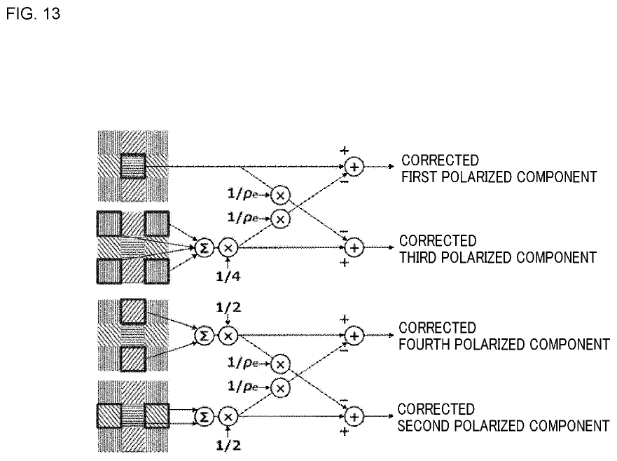

More specifically, as illustrated in FIG. 12 or FIG. 13, the polarized component measurement unit 91

obtains the first polarized component on the basis of the output signal from the first photoelectric conversion element 11₁,

obtains the (3-A)-th polarized component on the basis of the output signal from the (3-A)-th photoelectric conversion element 11_{3A},

obtains the (3-B)-th polarized component on the basis of the output signal from the (3-B)-th photoelectric conversion element 11_{3B}, obtains the (3-C)-th polarized component on the basis of the output signal from the (3-C)-th photoelectric conversion element 11_{3C}, and

obtains the (3-D)-th polarized component on the basis of the output signal from the (3-D)-th photoelectric conversion element 11_{3D}.

In addition, the polarized component calculation unit 92 calculates the corrected first polarized component by subtracting a value obtained by multiplying the obtained value of the polarized component of the third polarization azimuth (the average value of the (3-A)-th polarized component, the (3-B)-th polarized component, the (3-C)-th polarized component, and the (3-D)-th polarized component) by the reciprocal (1/ρₑ) of the extinction ratio from the obtained value of the first polarized component.

Likewise, the polarized component calculation unit 92 calculates the corrected third polarized component by subtracting a value obtained by multiplying the obtained value of the polarized component of the first polarization azimuth by the reciprocal (1/ρₑ) of the extinction ratio from the obtained value of the third polarized component (the average value of the (3-A)-th polarized component, the (3-B)-th polarized component, the (3-C)-th polarized component, and the (3-D)-th polarized component).

Likewise, the polarized component calculation unit 92 calculates the corrected second polarized component by subtracting a value obtained by multiplying the obtained value of the polarized component of the fourth polarization azimuth (the average value of the (4-A)-th polarized component and the (4-B)-th polarized component) by the reciprocal (1/ρₑ) of the extinction ratio from the obtained value of the second polarized component (the average value of the (2-A)-th polarized component and the (2-B)-th polarized component).

Likewise, the polarized component calculation unit 92 calculates the corrected fourth polarized component by subtracting a value obtained by multiplying the obtained value of the polarized component of the second polarization azimuth (the average value of the (2-A)-th polarized component and the (2-B)-th polarized component) by the reciprocal (1/ρₑ) of the extinction ratio from the obtained value of the fourth polarized component (the average value of the (4-A)-th polarized component and the (4-B)-th polarized component).

Meanwhile, although the average value of the (2-A)-th polarized component and the (2-B)-th polarized component is used as the second polarized component, the average value of the (3-A)-th polarized component, the (3-B)-th polarized component, the (3-C)-th polarized component and the (3-D)-th polarized component is used as the third polarized component, and the average value of the (4-A)-th polarized component and the (4-B)-th polarized component is used as the fourth polarized component, each polarized component is not limited to such an average value and may be modified in various manners in addition to average values through determination of spatial deviations of polarized components. Here, “average” refers to an arithmetic mean. However, it is not limited to the arithmetic mean, and a geometric mean or a geometric mean may be applied.

According to the light receiving device of embodiment 2, it is possible to promote improvement of resolution of polarization information because information on four types of polarization directions can be acquired in addition to the same effects as those of the light receiving device described in embodiment 1.

### Embodiment 3

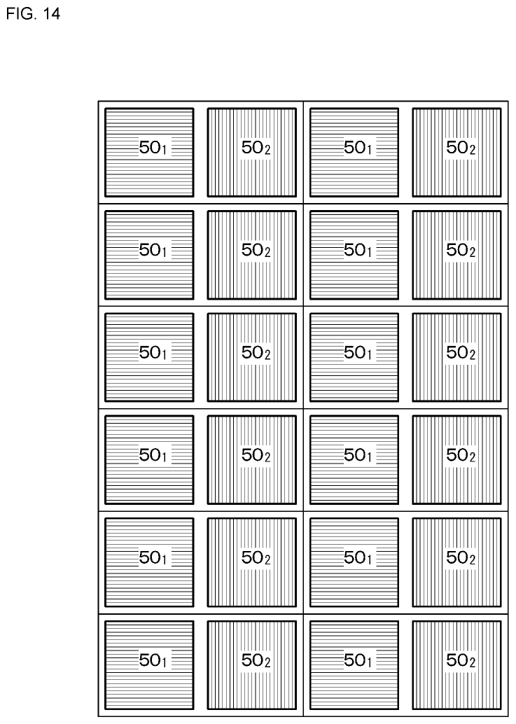

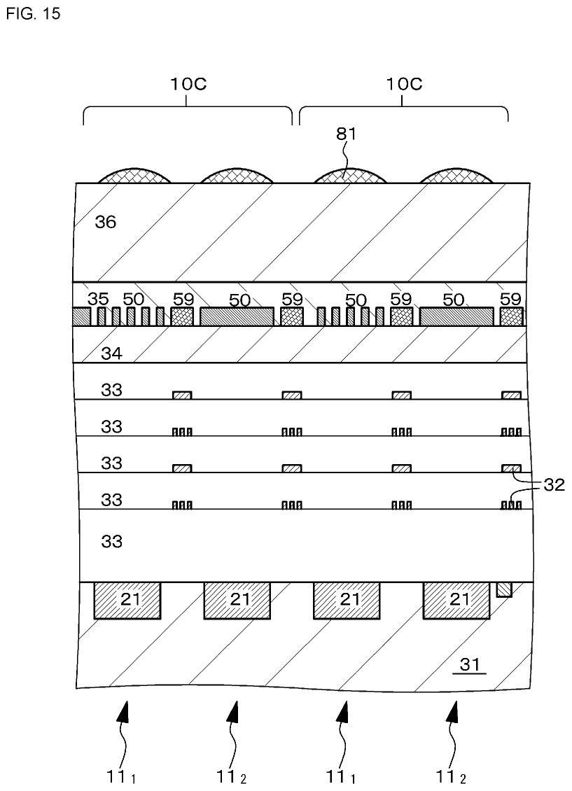

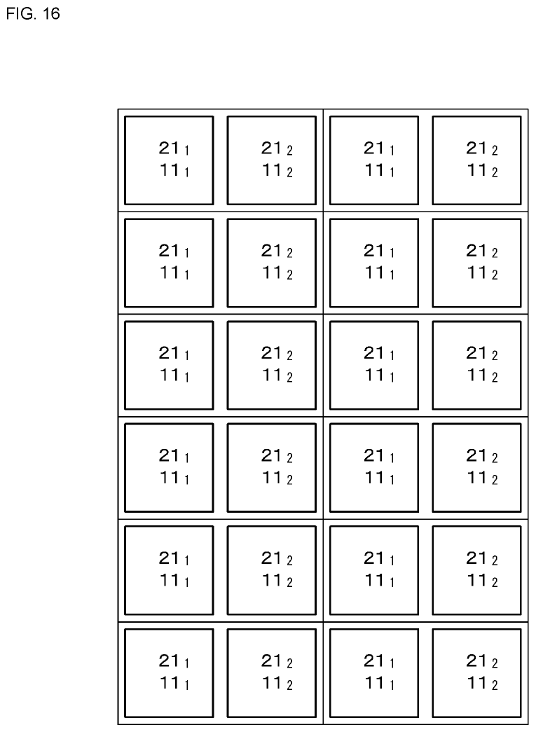

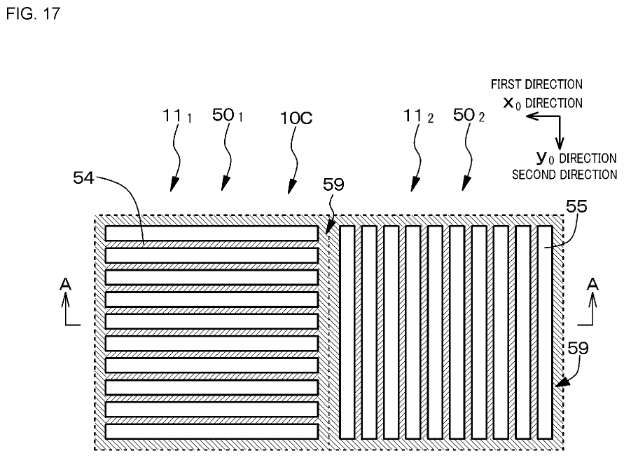

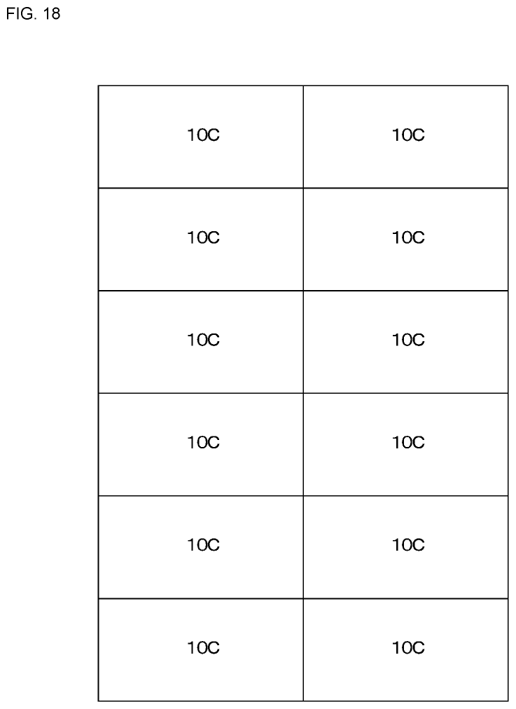

Embodiment 3 pertains to a light receiving device according to the first aspect of the present disclosure. A schematic plan view of wire grid polarization elements constituting photoelectric conversion elements of 2×6=12 photoelectric conversion element units in the light receiving device of embodiment 3 is illustrated in FIG. 14, a schematic partial cross-sectional view of the light receiving device of embodiment 3, taken along arrow A-A of FIG. 17 is illustrated in FIG. 15, and a conceptual plan view of photoelectric conversion parts is illustrated in FIG. 16. In addition, while a schematic plan view of wire grid polarization elements constituting photoelectric conversion elements of the light receiving device of embodiment 3 is illustrated in FIG. 17 and a schematic plan view of photoelectric conversion element groups is illustrated in FIG. 18, two photoelectric conversion element units constitute a single photoelectric conversion element group.

The light receiving device of embodiment 3 includes

a plurality of photoelectric conversion element unit 10C each composed of a first photoelectric conversion element 11₁ including a first polarization element 50₁ and a second photoelectric conversion element 11₂ including a second polarization element 50₂ and

further includes the polarized component measurement unit 91 and the polarized component calculation unit 92,

the first polarization element 50₁ has a first polarization azimuth of an angle of a degrees,

the second polarization element 50₂ has a second polarization azimuth of an angle of (α+90) degrees,

the polarized component measurement unit 91 obtains a first polarized component of incident light on the basis of an output signal from the first photoelectric conversion element 11₁ and obtains a second polarized component of the incident light on the basis of an output signal from the second photoelectric conversion element 11₂, and

the polarized component calculation unit 92 calculates a polarized component of the second polarization azimuth in the obtained first polarized component on the basis of the obtained second polarized component and calculates a polarized component of the first polarization azimuth in the obtained second polarized component on the basis of the obtained first polarized component.

In the light receiving device of embodiment 3, the polarized component calculation unit 92 calculates a corrected first polarized component by subtracting a value obtained by multiplying an obtained value of the polarized component of the second polarization azimuth by a reciprocal (1/ρₑ) of an extinction ratio from an obtained value of the first polarized component. In addition, the polarized component calculation unit 92 calculates a corrected second polarized component by subtracting a value obtained by multiplying an obtained value of the polarized component of the first polarization azimuth by the reciprocal (1/ρₑ) of the extinction ratio from an obtained value of the second polarized component. The first photoelectric conversion element 11₁ and the second photoelectric conversion element 11₂ are arranged in one direction. Specifically, the first photoelectric conversion element 11₁ and the second photoelectric conversion element 11₂ neighbor each other.

The light receiving device of embodiment 3 does not include the color filter layer 71 unlike the light receiving devices described in embodiment 1 and embodiment 2. The light receiving device of embodiment 3 having this configuration may be applied to a light receiving device (e.g., sensor) that does not aim at color separation or light separation, for example, and a photoelectric conversion element itself has sensitivity to a specific wavelength.

Except the aforementioned point, the configuration and the structure of the light receiving device of embodiment 3 may have the same configuration and structure of the light receiving device described in embodiment 1.

Each photoelectric conversion element constituting a photoelectric conversion element group of the light receiving device of embodiment 3 may include the color filter layer 71. Alternatively, photoelectric conversion elements constituting the light receiving device of embodiment 3 and photoelectric conversion elements that include the color filter layer and photoelectric conversion parts and do not include polarization elements may be combined to constitute a photoelectric conversion element unit.

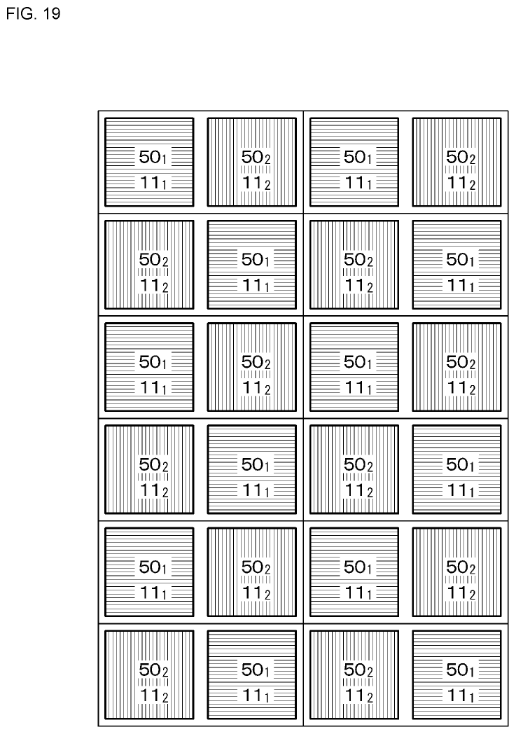

In some cases, as illustrated in a schematic plan view of wire grid polarization elements constituting photoelectric conversion elements in FIG. 19, a configuration in which a first photoelectric conversion element 11₁ constituting a certain photoelectric conversion element unit neighbors a total of four second photoelectric conversion elements 11₂ in the x₀ direction and the y₀ direction and a second photoelectric conversion element 11₂ constituting a certain photoelectric conversion element unit neighbors a total of four first photoelectric conversion elements 11₁ in the x₀ direction and the y₀ direction may also be employed. In addition, in this case, the polarized component calculation unit 92 calculates a corrected first polarized component by subtracting a value obtained by multiplying an average value of polarized components of the second polarization azimuth, obtained from the total of four neighboring second photoelectric conversion elements 11₂, by the reciprocal (1/ρₑ) of the extinction ratio from a value of the first polarized component obtained from the first photoelectric conversion element 11₁. In addition, the polarized component calculation unit 92 calculates a corrected second polarized component by subtracting a value obtained by multiplying an average value of polarized components of the first polarization azimuth, obtained from the total of four neighboring first photoelectric conversion elements 11₁, by the reciprocal (1/ρₑ) of the extinction ratio from a value of the second polarized component obtained from the second photoelectric conversion element 11₂.

Although the present disclosure has been described above on the basis of preferred embodiments, the present disclosure is not limited to such embodiments. Structures, configurations, manufacturing methods, and used materials of the photoelectric conversion elements (light receiving elements, imaging elements), the light receiving devices, and the solid-state imaging devices described in the embodiments are exemplary and may be appropriately modified. Images may be captured and sensed using a solid-state imaging device based on light receiving devices of the present disclosure. Combinations of photoelectric conversion parts, a wavelength selection means, and wire grid polarization elements described in the embodiments may be appropriately modified. Photoelectric conversion parts for near infrared light (or photoelectric conversion parts for infrared light) may be included. Although the wire grid polarization elements are used exclusively to acquire polarization information in photoelectric conversion parts having sensitivity to the visible light wavelength range in the above-described embodiments, in a case where the photoelectric conversion parts have sensitivity to infrared rays or ultraviolet rays, the wire grid polarization elements may be implemented as wire grid polarization elements that function in an arbitrary wavelength range by extending or reducing the formation pitch P₀ of line parts in response to the case.

Hereinafter, modified examples of the light receiving devices of embodiment 1 and embodiment 3 will be described.

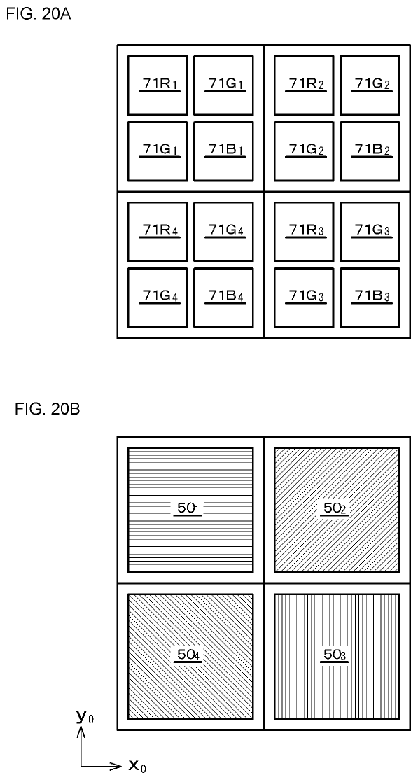

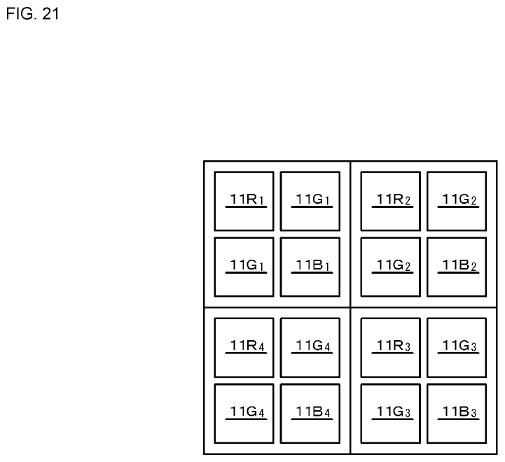

As illustrated in schematic partial plan views of a first modified example of wavelength selection means (color filter layer) and wire grid polarization elements in the light receiving device of embodiment 1 in FIG. 20A and FIG. 20B, and a schematic partial plan view of photoelectric conversion elements in FIG. 21, in four photoelectric convention element units, a first photoelectric conversion element unit is composed of a photoelectric conversion element 11R₁ for red light which absorbs red light, photoelectric conversion elements 11G₁ and 11G₁ for green light which absorb green light, a photoelectric conversion element 11B₁ for blue light which absorbs blue light, and wavelength selection means (color filter layers) 71R₁, 71G₁, 71G₁, and 71B₁ for these photoelectric conversion elements, a second photoelectric conversion element unit is composed of a photoelectric conversion element 11R₂ for red light which absorbs red light, photoelectric conversion elements 11G₂ and 11G₂ for green light which absorb green light, a photoelectric conversion element 11B₂ for blue light which absorbs blue light, and wavelength selection means (color filter layers) 71R₂, 71G₂, 71G₂, and 71B₂ for these photoelectric conversion elements, a third photoelectric conversion element unit is composed of a photoelectric conversion element 11R₃ for red light which absorbs red light, photoelectric conversion elements 11G₃ and 11G₃ for green light which absorb green light, a photoelectric conversion element 11B₃ for blue light which absorbs blue light, and wavelength selection means (color filter layers) 71R₃, 71G₃, 71G₃, and 71B₃ for these photoelectric conversion elements, and a fourth photoelectric conversion element unit is composed of a photoelectric conversion element 11R₄ for red light which absorbs red light, photoelectric conversion elements 11G₄ and 11G₄ for green light which absorb green light, a photoelectric conversion element 11B₄ for blue light which absorbs blue light, and wavelength selection means (color filter layers) 71R₄, 71G₄, 71G₄, and 71B₄ for these photoelectric conversion elements. In addition, a single wire grid polarization element is provided for each photoelectric conversion element unit. Here, a polarization azimuth required for transmission of a wire grid polarization element 50₁ is α degrees, a polarization azimuth required for transmission of a wire grid polarization element 50₂ is (α+45) degrees, a polarization azimuth required for transmission of a wire grid polarization element 50₃ is (α+90) degrees, and a polarization azimuth required for transmission of a wire grid polarization element 50₄ is (α+135) degrees.

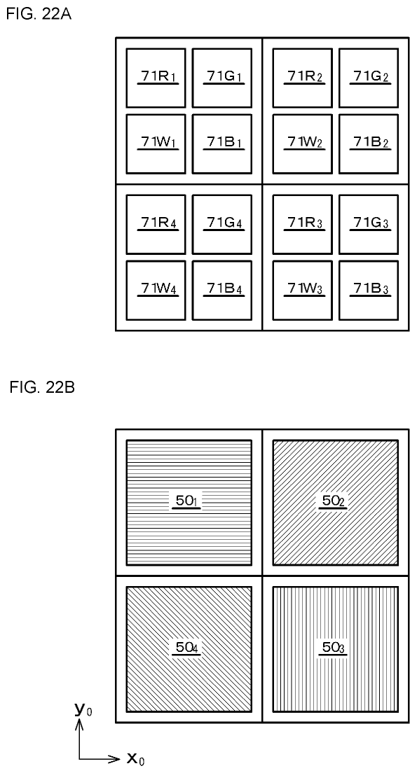

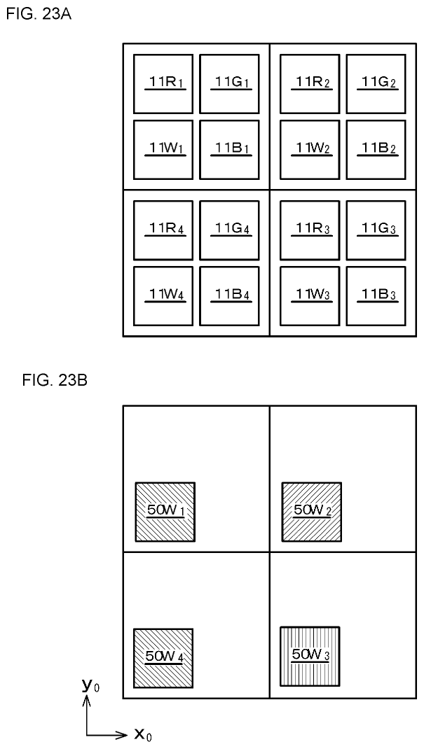

As illustrated in schematic partial plan views of a second modified example of wavelength selection means (color filter layer) and wire grid polarization elements in the light receiving device of embodiment 1 in FIG. 22A and FIG. 22B, and a schematic partial plan view of photoelectric conversion elements in FIG. 23A, in four photoelectric convention element units, a first photoelectric conversion element unit is composed of a photoelectric conversion element 11R₁ for red light which absorbs red light, a photoelectric conversion element 11G₁ for green light which absorbs green light, a photoelectric conversion element 11B₁ for blue light which absorbs blue light, a photoelectric conversion element 11W₁ for white light which absorbs white light, and wavelength selection means (color filter layers) 71R₁, 71G₁, and 71B₁ and a transparent resin layer 71W₁ for these photoelectric conversion elements, a second photoelectric conversion element unit is composed of a photoelectric conversion element 11R₂ for red light which absorbs red light, a photoelectric conversion element 11G₂ for green light which absorbs green light, a photoelectric conversion element 11B₂ for blue light which absorbs blue light, a photoelectric conversion element 11W₂ for white light which absorbs white light, and wavelength selection means (color filter layers) 71R₂, 71G₂, and 71B₂ and a transparent resin layer 71W₂ for these photoelectric conversion elements, a third photoelectric conversion element unit is composed of a photoelectric conversion element 11R₃ for red light which absorbs red light, a photoelectric conversion element 11G₃ for green light which absorbs green light, a photoelectric conversion element 11B₃ for blue light which absorbs blue light, a photoelectric conversion element 11W₃ for white light which absorbs white light, and wavelength selection means (color filter layers) 71R₃, 71G₃, and 71B₃ and a transparent resin layer 71W₃ for these photoelectric conversion elements, and a fourth photoelectric conversion element unit is composed of a photoelectric conversion element 11R₄ for red light which absorbs red light, a photoelectric conversion element 11G₄ for green light which absorbs green light, a photoelectric conversion element 11B₄ for blue light which absorbs blue light, a photoelectric conversion element 11W₄ for white light which absorbs white light, and wavelength selection means (color filter layers) 71R₄, 71G₄, and 71B₄ and a transparent resin layer 71W₄ for these photoelectric conversion elements. Meanwhile, photoelectric conversion elements having sensitivity to white light may have sensitivity to light of 425 nm to 750 nm, for example. In addition, a single wire grid polarization element is provided for each photoelectric conversion element unit. Here, a polarization azimuth required for transmission of a wire grid polarization element 50₁ is α degrees, a polarization azimuth required for transmission of a wire grid polarization element 50₂ is (α+45) degrees, a polarization azimuth required for transmission of a wire grid polarization element 50₃ is (α+90) degrees, and a polarization azimuth required for transmission of a wire grid polarization element 50₄ is (α+135) degrees. Alternatively, as illustrated in a schematic partial plan view of photoelectric conversion elements in FIG. 23B, wire grid polarization elements 50W₁, 50W₂, 50W₃, and 50W₄ are provided only above the photoelectric conversion elements 11W₁, 11W₂, 11W₃, and 11W₄.

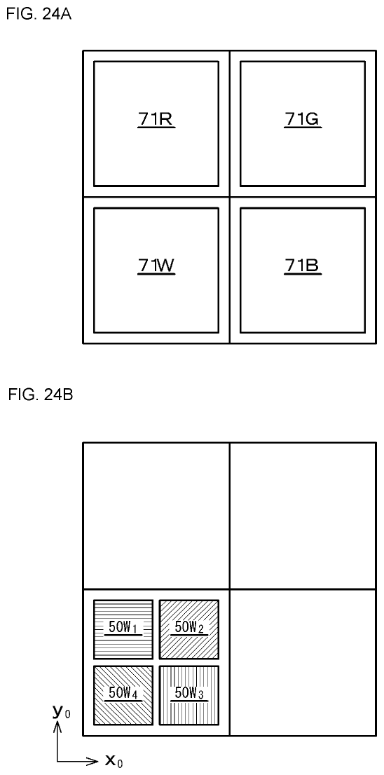

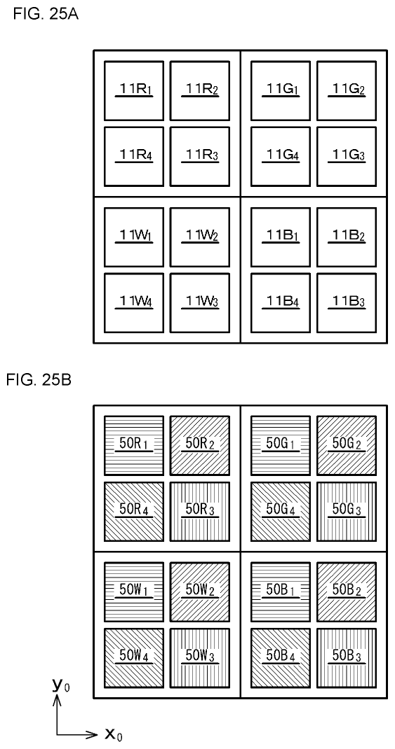

As illustrated in schematic partial plan views of a third modified example of wavelength selection means (color filter layer) and wire grid polarization elements in the light receiving device of embodiment 1 in FIG. 24A and FIG. 24B, and a schematic partial plan view of photoelectric conversion elements in FIG. 25A, in four photoelectric convention element units, a first photoelectric conversion element unit is composed of four photoelectric conversion elements 11R₁, 11R₂, 11R₃, and 11R₄, a second photoelectric conversion element unit is composed of four photoelectric conversion elements 11G₁, 11G₂, 11G₃, and 11G₄, a third photoelectric conversion element unit is composed of four photoelectric conversion elements 11B₁, 11B₂, 11B₃, and 11B₄, and a fourth photoelectric conversion element unit is composed of four photoelectric conversion elements 11W₁, 11W₂, 11W₃, and 11W₄. In addition, wavelength selection means (color filter layers) 71R, 71G, and 71B and a transparent resin layer 71W for the photoelectric conversion elements 11R₁, 11R₂, 11R₃, and 11R₄ for red light, the photoelectric conversion elements 11G₁, 11G₂, 11G₃, and 11G₄ for green light, the photoelectric conversion elements for blue light 11B₁, 11B₂, 11B₃, and 11B₄, and the photoelectric conversion elements 11W₁, 11W₂, 11W₃, and 11W₄ for white light are provided. In addition, the four wire grid polarization elements 50W₁, 50W₂, 50W₃, and 50W₄ are provided for the photoelectric conversion elements 11W₁, 11W₂, 11W₃, and 11W₄ for white light. Here, a polarization azimuth required for transmission of a wire grid polarization element 50W₁ is α degrees, a polarization azimuth required for transmission of a wire grid polarization element 50W₂ is (α+45) degrees, a polarization azimuth required for transmission of a wire grid polarization element 50W₃ is (α+90) degrees, and a polarization azimuth required for transmission of a wire grid polarization element 50W₄ is (α+135) degrees.

Meanwhile, as illustrated in a schematic partial plan view of a third modified example of wire grid polarization elements in FIG. 25B, four wire grid polarization elements 50R₁, 50R₂, 50R₃, and 50R₄/50G₁, 50G₂, 50G₃, and 50G₄/50B₁, 50B₂, 50B₃, and 50B₄/50W₁, 50W₂, 50W₃, and 50W₄ may be provided for each photoelectric conversion element unit (1 pixel).

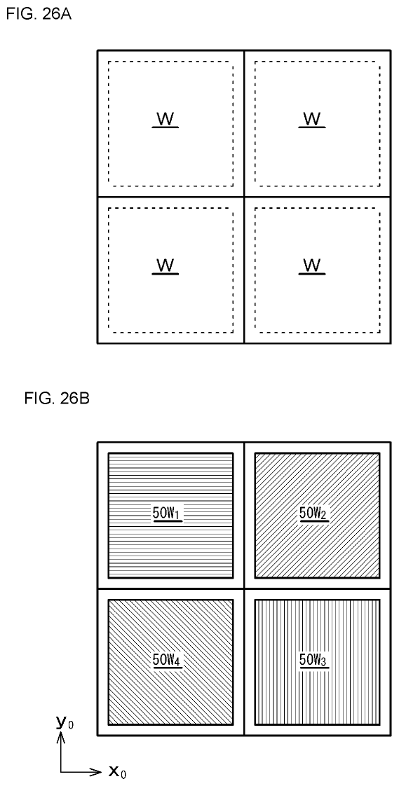

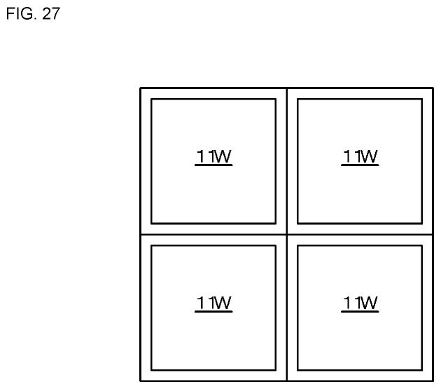

As illustrated in schematic partial plan views of a fifth modified example of wavelength selection means (color filter layer) and wire grid polarization elements in the light receiving device of embodiment 1 in FIG. 26A and FIG. 26B, and a schematic partial plan view of photoelectric conversion elements in FIG. 27, the light receiving device may be composed of only photoelectric conversion elements for white light 11W although it depends on specifications required for the light receiving device.

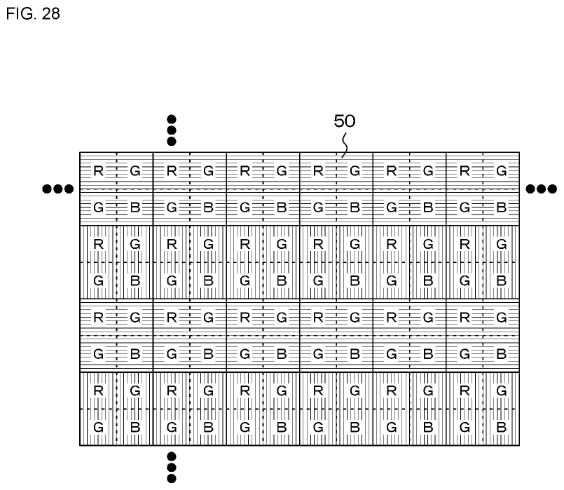

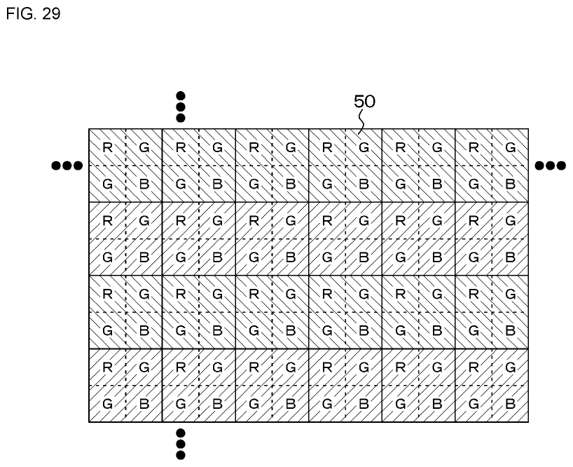

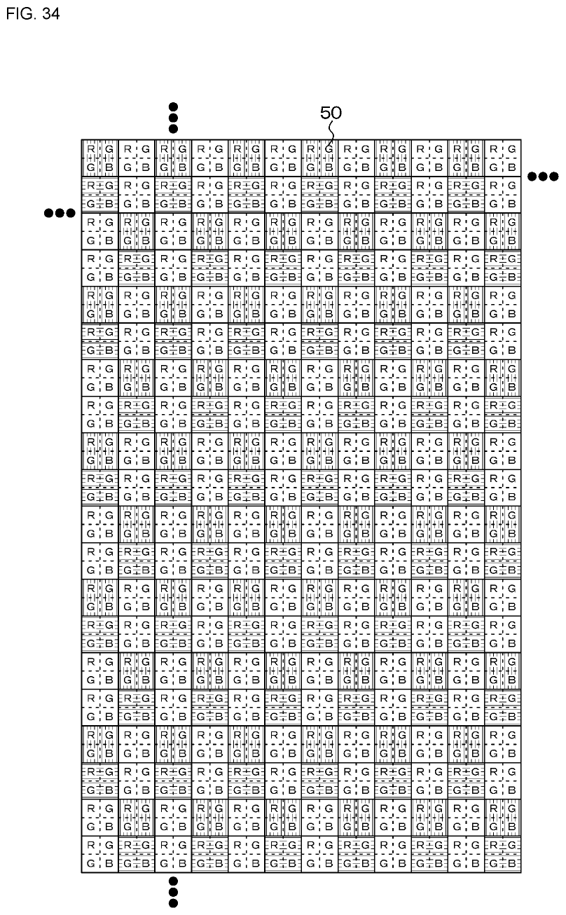

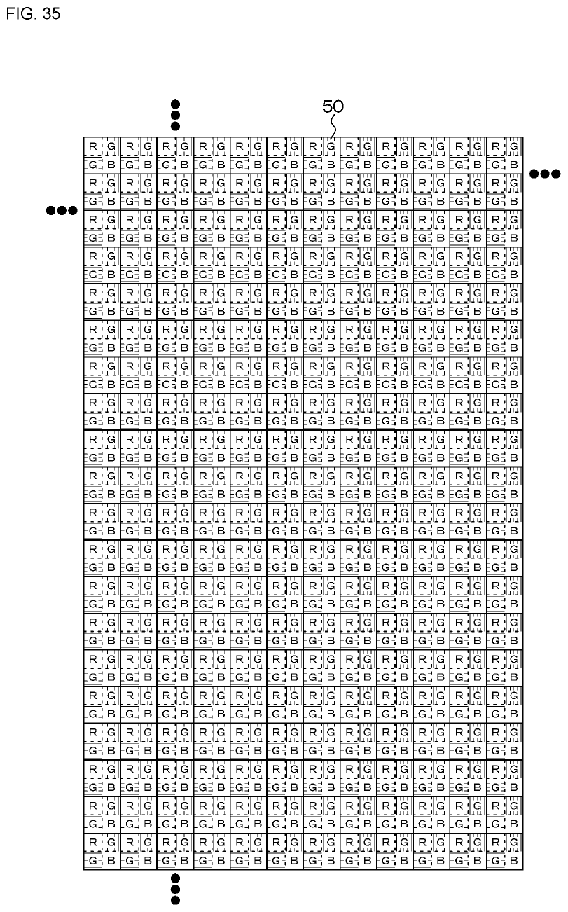

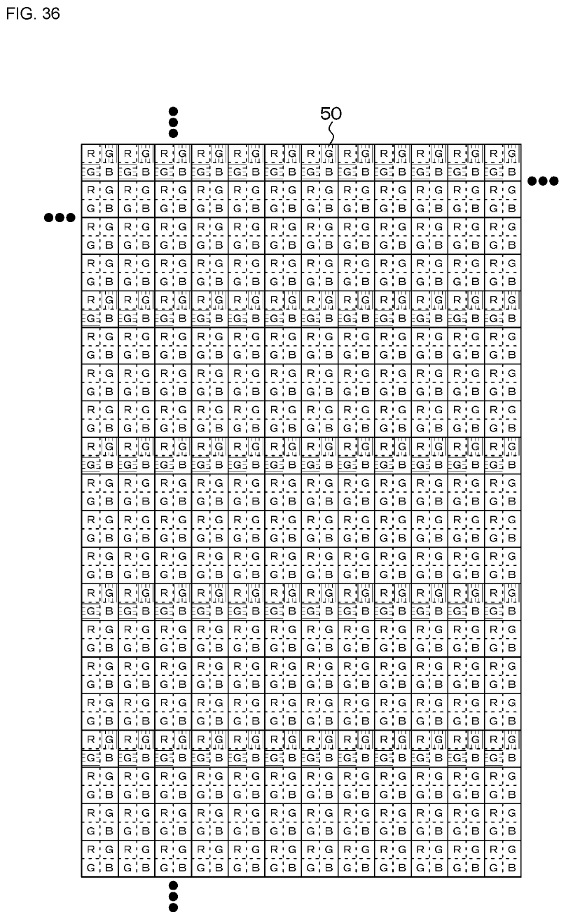

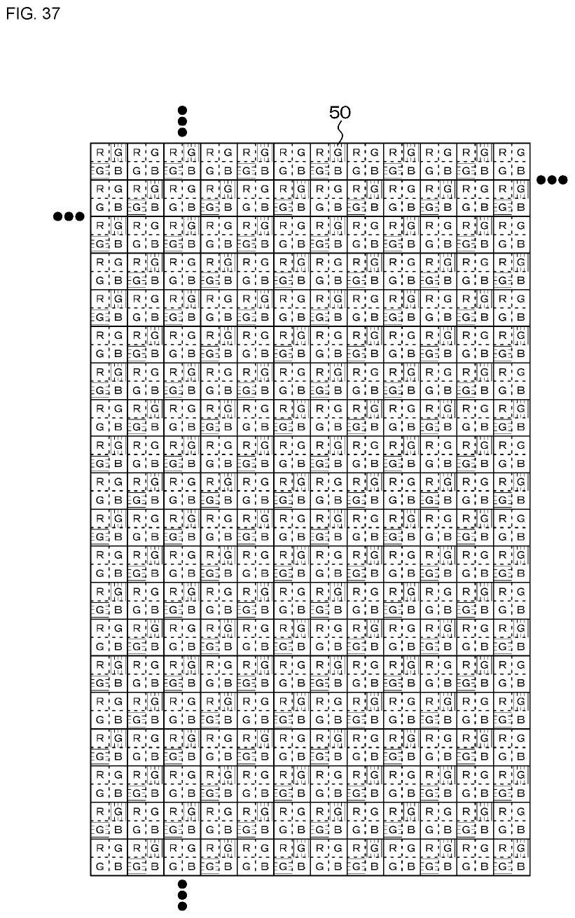

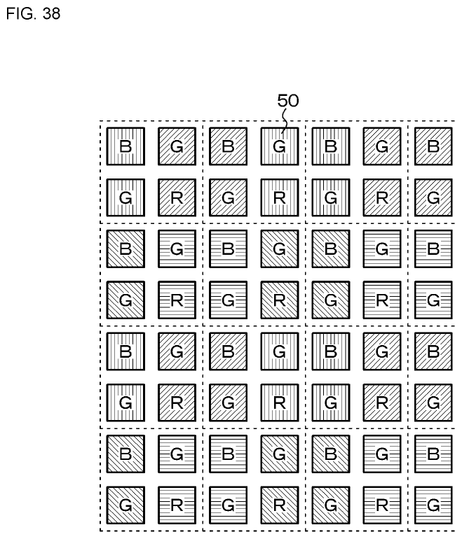

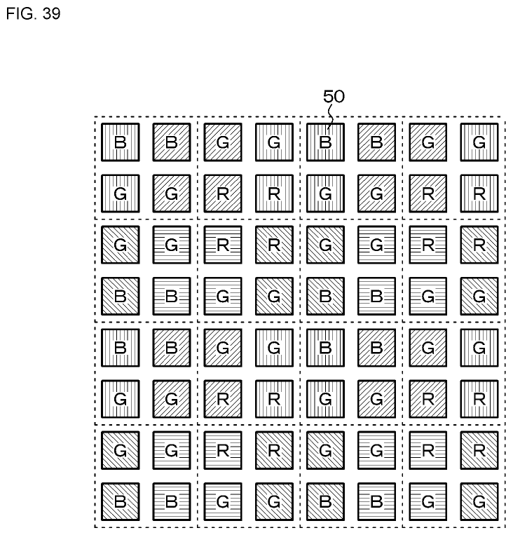

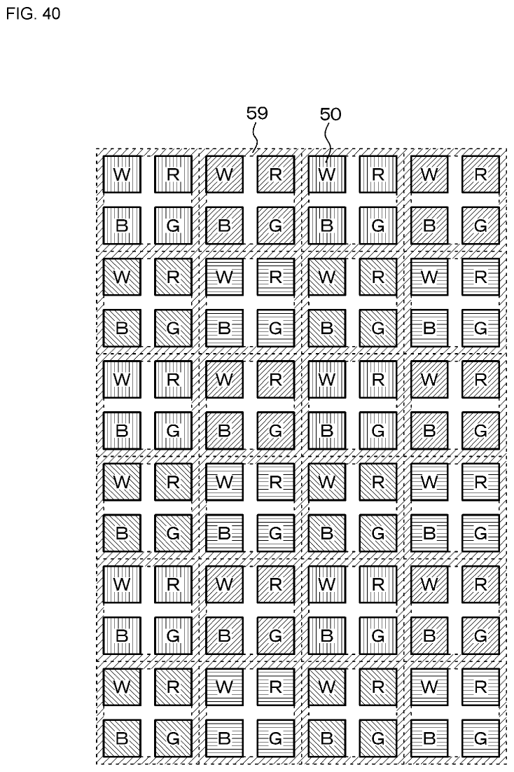

As a modified example of the light receiving device of embodiment 3, photoelectric conversion elements having, for example, an angle of 0 degrees between a direction in which a plurality of photoelectric conversion elements are arranged and the first direction and photoelectric conversion elements having an angle of 180 degrees therebetween may be combined, as illustrated in FIG. 28. In addition, photoelectric conversion elements having, for example, an angle of 45 degrees between a direction in which a plurality of photoelectric conversion elements are arranged and the first direction and photoelectric conversion elements having an angle of 135 degrees therebetween may be combined, as illustrated in FIG. 29. Meanwhile, in plane layout diagrams of photoelectric conversion element units illustrated in FIG. 28 to FIG. 40, “R” represents a photoelectric conversion element for red light including a red color filter layer, “G” represents a photoelectric conversion element for green light including a green color filter layer, “B” represents a photoelectric conversion element for blue light including a blue color filter layer, and “W” represents a photoelectric conversion element for white light including no color filter layer.

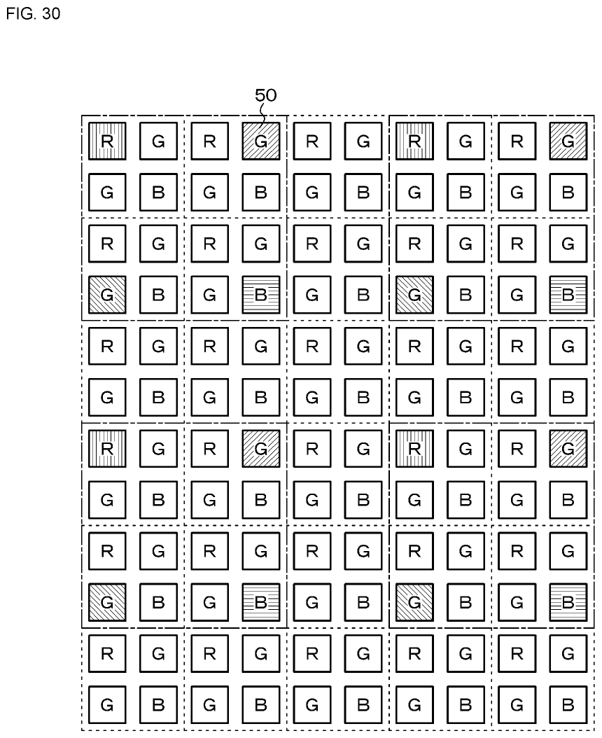

Although photoelectric conversion elements W for white light including wire grid polarization elements 50 are arranged with one photoelectric conversion element skipped in the x₀ direction and the y₀ direction in the example illustrated in FIG. 23B, they may be arranged with two or three photoelectric conversion elements skipped, or photoelectric conversion elements including the wire grid polarization elements 50 may be arranged in a houndstooth form. The plane layout diagram of FIG. 30 is a modified example of the example illustrated in FIG. 23B.

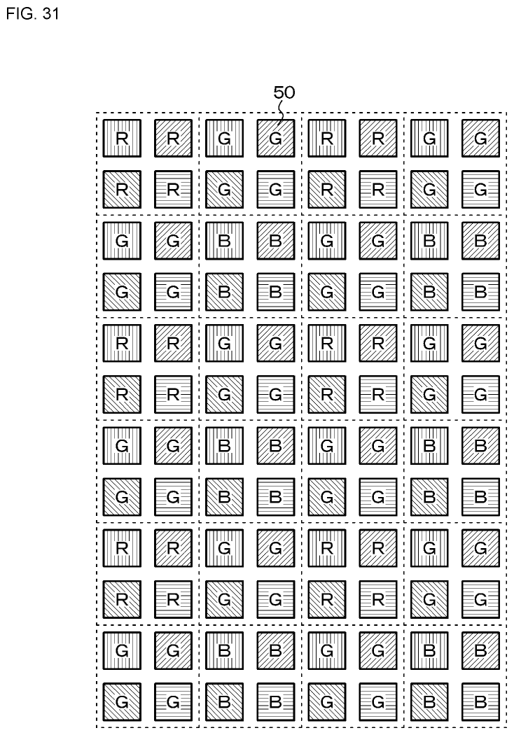

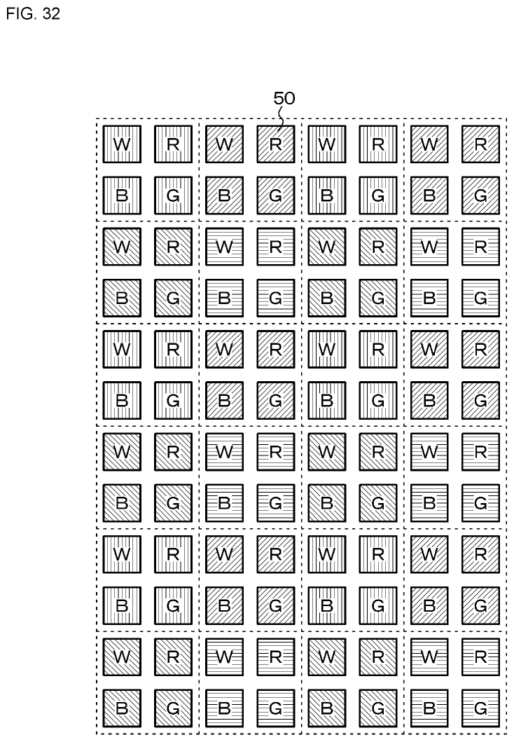

Configurations illustrated in the plane layout diagrams of FIG. 31 and FIG. 32 may be employed. Here, in the case of a CMOS image sensor having the plane layout illustrated in FIG. 31, a 2×2 pixel sharing method of sharing a select transistor, a reset transistor, and an amplification transistor in 2×2 photoelectric conversion elements can be employed, imaging including polarization information can be performed in an imaging mode in which pixel addition is not performed, and a general captured image in which all polarized components have been integrated can be provided in a mode in which FD addition of accumulated charges of 2×2 subpixel regions is performed. In addition, in the case of the plane layout illustrated in FIG. 32, wire grid polarization elements are arranged in one direction for 2×2 photoelectric conversion elements, and thus discontinuity of laminated structures hardly occur between photoelectric conversion element units so that polarization imaging with high quality can be realized.

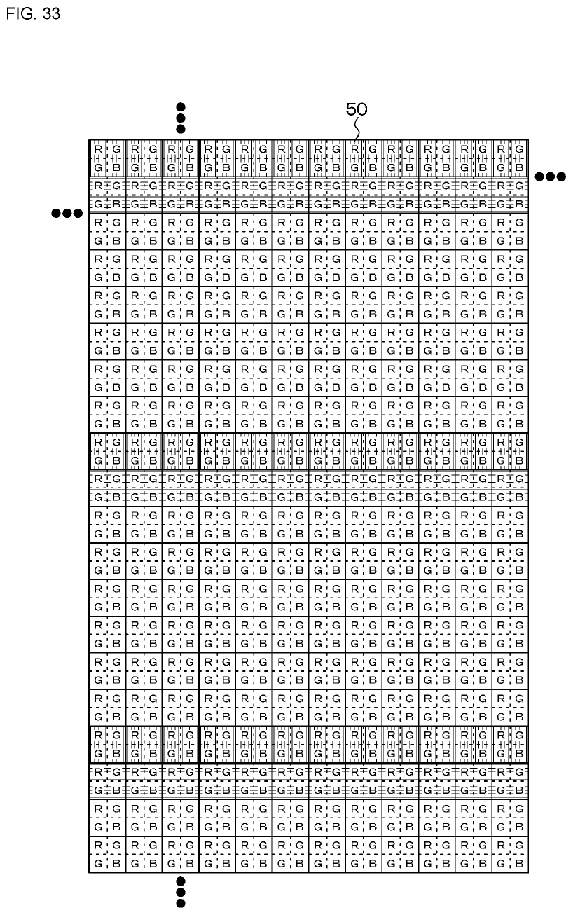

Furthermore, configurations illustrated in plane layouts illustrated in FIG. 33 to FIG. 40 may be employed.

In addition, it is possible to configure, for example, a digital still camera or a video camera, a camcorder, a monitoring camera, a vehicle-mounted camera (in-vehicle camera), a smartphone camera, a user interface camera for games, a biometric authentication camera, and the like using the light receiving devices (solid-state imaging devices) of the embodiments. That is, the light receiving devices of the embodiments can be configured as a light receiving device (solid-state imaging device) capable of simultaneously acquiring polarization information in addition to functions as conventional photoelectric conversion elements (i.e., addition to conventional imaging). That is, the light receiving device (solid-state imaging device) is provided with a polarization separation function of spatially polarization-separating polarization information of incident light. Specifically, since light intensity, polarized component intensity, and a polarization direction can be obtained in each photoelectric conversion element (imaging element), image data can be processed on the basis of polarization information after imaging, for example. It is possible to emphasize or reduce a polarized component or separate various polarized components by adding desired processing to a part of a captured image of the sky or a window glass, a part of a captured image of the surface of the water, or the like, for example, and thus the contrast of an image can be improved and unnecessary information can be deleted. Specifically, for example, reflection on a window glass can be removed, and sharpening of boundaries (outlines) of a plurality of objects can be promoted by adding polarization information to image information. Alternatively, a state of a road surface and an obstacle on a road surface may be detected. Further, the light receiving devices can be applied to various fields such as imaging of a pattern in which birefringence of an object has been reflected, measurement of a retardation distribution, acquisition of a polarizing microscope image, acquisition of a surface shape of an object, measurement of surface quality of an object, detection of a moving body (vehicle or the like), and weather observation such as measurement of a cloud distribution or the like. In addition, the light receiving devices may be configured as solid-state imaging devices for capturing stereoscopic images.

In some cases, a configuration in which a trench (a kind of element separation region) that extends from the substrate to the bottom of the wire grid polarization elements and is filled with an insulating material or a light shielding material is formed around the photoelectric conversion parts may be employed. A material forming an insulating film (insulating film formation layer) or an interlayer insulating layer may be conceived as the insulating material, and the material forming the aforementioned light shielding film 24 may be conceived as the light shielding material. By forming such a trench, it is possible to prevent sensitivity reduction, generation of polarization crosstalk, and extinction ratio reduction.

A waveguide structure may be provided between the photoelectric conversion parts 21. The waveguide structure is configured using a thin film that is formed in a region (e.g., a cylindrical region) positioned between the photoelectric conversion parts 21 in the lower interlayer insulating layer 33 (specifically, a part of the lower interlayer insulating layer 33) covering the photoelectric conversion parts 21 and has a refractive index value greater than the refractive index value of the material forming the lower interlayer insulating layer 33. In addition, light incident from above the photoelectric conversion parts 21 is total-reflected by this thin film to arrive at the photoelectric conversion parts 21. An orthographic projection image of the photoelectric conversion parts 21 with respect to the semiconductor substrate 31 is positioned inside an orthographic projection image of the thin film constituting the waveguide structure with respect to the semiconductor substrate 31. In addition, the orthographic projection image of the photoelectric conversion parts 21 with respect to the semiconductor substrate 31 is surrounded by the orthographic projection image of the thin film constituting the waveguide structure with respect to the substrate.

Alternatively, a light-concentrating tube structure may be provided between the photoelectric conversion parts 21. The light-concentrating tube structure is configured using a light-shielding thin film formed of a metal material or an alloy material in a region (e.g., a cylindrical region) positioned between the photoelectric conversion parts 21 in the lower interlayer insulating layer 33 covering the photoelectric conversion parts 21, and light incident from above the photoelectric conversion parts 21 is reflected by this thin film to arrive at the photoelectric conversion parts 21. That is, an orthographic projection image of the photoelectric conversion parts 21 with respect to the semiconductor substrate 31 is positioned inside an orthographic projection image of the thin film constituting the light-concentrating tube structure with respect to the semiconductor substrate 31. In addition, the orthographic projection image of the photoelectric conversion parts 21 with respect to the semiconductor substrate 31 is surrounded by the orthographic projection image of the thin film constituting the light-concentrating tube structure with respect to the semiconductor substrate 31. For example, the thin film may be obtained by forming a ring-shaped trench in the lower interlayer insulating layer 33 after formation of the all lower interlayer insulating layer 33 and filling the trench with a metal material or an alloy material.

A pixel sharing method of sharing a select transistor, a reset transistor, and an amplification transistor in a plurality of photoelectric conversion parts (photoelectric conversion elements) such as 2×2 photoelectric conversion parts can be employed, imaging including polarization information can be performed in an imaging mode in which pixel addition is not performed, and a general captured image in which all polarized components have been integrated can be provided in a mode in which FD addition of accumulated charges of a plurality of subpixel regions such as 2×2 subpixel regions is performed.

In addition, a case in which the present disclosure is applied to a CMOS type solid-state imaging device configured in such a manner that unit pixels for detecting signal charges in response to the amount of incident light as a physical quantity are arranged in a matrix form has been described as an example in the embodiments, the present disclosure is not limited to application to the CMOS type solid-state imaging device and may be applied to a CCD type solid-state imaging device. In the latter case, signal charges are transferred by a vertical transfer register in a CCD type structure in the vertical direction and transferred by a horizontal transfer register in the horizontal direction and amplified to output a pixel signal (image signal). Further, the present disclosure is not limited to column type solid-state imaging devices in which pixels are formed in a two-dimensional matrix forms and a column signal processing circuit is provided for each pixel column. Further, select transistors may be omitted in some cases.

Moreover, the photoelectric conversion elements (imaging elements) of the present disclosure are not limited to application to a solid-state imaging device that detects a distribution of amounts of incident light of visible light and captures it as an image and may also be applied to a solid-state imaging device that captures a distribution of amounts of incidence of infrared rays, X rays, particles, or the like an image. In addition, the photoelectric conversion elements may be applied to solid-state imaging devices (physical quantity distribution detection devices) such as a fingerprint detection sensor, which detect distributions of other physical quantities such as pressure and capacitance and capture them as images in a broad sense.

Furthermore, the present disclosure is not limited to a solid-state imaging device that sequentially scans unit pixels of an imaging area in units of row to read a pixel signal from each unit pixel. The present disclosure may also be applied to an X-Y address type solid-state imaging device that selects an arbitrary pixel in units of unit pixel and reads a pixel signal from the selected pixel in units of unit pixel. Solid-state imaging devices may have a one-chip form or a modular form having an image function in which an imaging area and a driving circuit or an optical system are integrated in a package.

In addition, the present disclosure is not limited to application to solid-state imaging devices and may also be applied to imaging devices. Here, imaging devices refer to camera systems such as a digital still camera and a video camera, and electronic apparatuses having an imaging function such as a cellular phone. There are cases in which a modular form mounted in an electronic apparatus, that is, a camera module is configured as an imaging device.

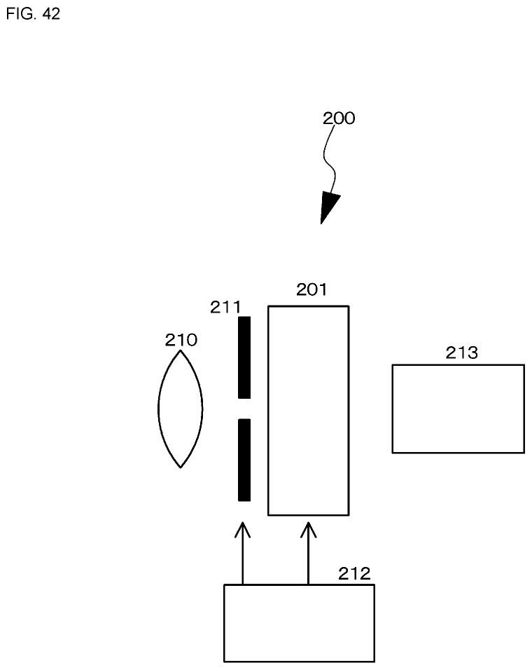

An example in which a solid-state imaging device 201 of the present disclosure is used for an electronic apparatus (camera) 200 is illustrated in FIG. 42 as a conceptual diagram. The electronic apparatus 200 includes a solid-state imaging device 201, an optical lens 210, a shutter device 211, a driving circuit 212, and a signal processing circuit 213. The optical lens 210 images an image light (incident light) from a subject on an imaging plane of the solid-state imaging device 201. Accordingly, signal charges are accumulated in the solid-state imaging device 201 for a specific period. The shutter device 211 controls a light radiation period and a light shielding period for the solid-state imaging device 201. The driving circuit 212 supplies driving signals for controlling a transfer operation of the solid-state imaging device 201 and a shutter operation of the shutter device 211. Signal transfer of the solid-state imaging device 201 is performed according to a driving signal (timing signal) supplied from the driving circuit 212. The signal processing circuit 213 performs various types of signal processing. A video signal on which signal processing has been performed is stored in a storage medium such as a memory or output to a monitor. In this electronic apparatus 200, reduction of a pixel size and improvement of transfer efficiency in the solid-state imaging device 201 can be achieved, and thus the electronic apparatus 200 with improved pixel characteristics can be obtained. The electronic apparatus 200 to which the solid-state imaging device 201 can be applied is not limited to cameras and may be applied to imaging devices such as a digital still camera, and a camera module for mobile apparatuses such as a cellular phone.

Meanwhile, the present disclosure may take the following configurations.

[A01]

<<Light Receiving Device: First Aspect>>

A light receiving device including a plurality of photoelectric conversion element units each composed of a first photoelectric conversion element including a first polarization element and a second photoelectric conversion element including a second polarization element, and

further including a polarized component measurement unit and a polarized component calculation unit, wherein

the first polarization element has a first polarization azimuth of an angle of α degrees,

the second polarization element has a second polarization azimuth of an angle of (α+90) degrees,

the polarized component measurement unit obtains a first polarized component of incident light on the basis of an output signal from the first photoelectric conversion element and obtains a second polarized component of the incident light on the basis of an output signal from the second photoelectric conversion element, and

the polarized component calculation unit calculates a polarized component of the second polarization azimuth in the obtained first polarized component on the basis of the obtained second polarized component and calculates a polarized component of the first polarization azimuth in the obtained second polarized component on the basis of the obtained first polarized component.

[A02]

The light receiving device according to [A01], wherein the polarized component calculation unit calculates a corrected first polarized component by subtracting a value obtained by multiplying an obtained value of the polarized component of the second polarization azimuth by a reciprocal of an extinction ratio from an obtained value of the first polarized component, and calculates a corrected second polarized component by subtracting a value obtained by multiplying an obtained value of the polarized component of the first polarization azimuth by the reciprocal of the extinction ratio from an obtained value of the second polarized component.

[A03]

The light receiving device according to [A01] or [A02], wherein the first photoelectric conversion element and the second photoelectric conversion element are arranged in one direction (e.g., they are adjacent to each other).

[B01]

<<Light Receiving Device: Second Aspect>>

A light receiving device including a plurality of photoelectric conversion element units each composed of a first photoelectric conversion element including a first polarization element, a second photoelectric conversion element including a second polarization element, a third photoelectric conversion element including a third polarization element, and a fourth photoelectric conversion element including a fourth polarization element, and

further including a polarized component measurement unit and a polarized component calculation unit, wherein

the first polarization element has a first polarization azimuth of an angle of α degrees,

the second polarization element has a second polarization azimuth of an angle of (α+45) degrees,

the third polarization element has a third polarization azimuth of an angle of (α+90) degrees,

the fourth polarization element has a fourth polarization azimuth of an angle of (α+135) degrees,

the polarized component measurement unit

obtains a first polarized component of incident light on the basis of an output signal from the first photoelectric conversion element,

obtains a second polarized component of the incident light on the basis of an output signal from the second photoelectric conversion element,

obtains a third polarized component of the incident light on the basis of an output signal from the third photoelectric conversion element, and

obtains a fourth polarized component of the incident light on the basis of an output signal from the fourth photoelectric conversion element, and

the polarized component calculation unit

calculates a polarized component of the third polarization azimuth in the obtained first polarized component on the basis of the obtained third polarized component,

calculates a polarized component of the first polarization azimuth in the obtained third polarized component on the basis of the obtained first polarized component,

calculates a polarized component of the fourth polarization azimuth in the obtained second polarized component on the basis of the obtained fourth polarized component, and

calculates a polarized component of the second polarization azimuth in the obtained fourth polarized component on the basis of the obtained second polarized component.

[B02]

The light receiving device according to [B01], wherein the polarized component calculation unit

calculates a corrected first polarized component by subtracting a value obtained by multiplying an obtained value of the polarized component of the third polarization azimuth by a reciprocal of an extinction ratio from an obtained value of the first polarized component,

calculates a corrected third polarized component by subtracting a value obtained by multiplying an obtained value of the polarized component of the first polarization azimuth by the reciprocal of the extinction ratio from an obtained value of the third polarized component,

calculates a corrected second polarized component by subtracting a value obtained by multiplying an obtained value of the polarized component of the fourth polarization azimuth by the reciprocal of the extinction ratio from an obtained value of the second polarized component, and

calculates a corrected fourth polarized component by subtracting a value obtained by multiplying an obtained value of the polarized component of the second polarization azimuth by the reciprocal of the extinction ratio from an obtained value of the fourth polarized component.

[B03]

The light receiving device according to [B01] or [B02], wherein the plurality of photoelectric conversion elements are arranged in a two-dimensional matrix form in the x₀ direction and the y₀ direction,

a photoelectric conversion element unit is composed of a single first photoelectric conversion element, a single second photoelectric conversion element, a single third photoelectric conversion element, and a single fourth photoelectric conversion element,

the first photoelectric conversion element and the second photoelectric conversion element are arranged in the x₀ direction,

the third photoelectric conversion element and the fourth photoelectric conversion element are arranged in the x₀ direction,

the first photoelectric conversion element and the fourth photoelectric conversion element are arranged in the y₀ direction, and

the second photoelectric conversion element and the third photoelectric conversion element are arranged in the y₀ direction.

[B04]

The light receiving device according to [B01] or [B02], wherein the plurality of photoelectric conversion elements are arranged in a two-dimensional matrix form in the x₀ direction and the y₀ direction,

a photoelectric conversion unit is composed of a single first photoelectric conversion element, two second photoelectric conversion elements including a (2-A)-th photoelectric convention element and a (2-B)-th photoelectric conversion element, four third photoelectric conversion elements including a (3-A)-th photoelectric convention element, a (3-B)-th photoelectric conversion element, a (3-C)-th photoelectric convention element, and a (3-D)-th photoelectric conversion element, and two fourth photoelectric conversion elements including a (4-A)-th photoelectric conversion element and a (4-B)-th photoelectric conversion element,

the (3-A)-th photoelectric conversion element, the (4-A)-th photoelectric conversion element, and the (3-B)-th photoelectric conversion element are arranged adjacently in the x₀ direction,

the (2-A)-th photoelectric conversion element, the first photoelectric conversion element, and the (2-B)-th photoelectric conversion element are arranged adjacently in the x₀ direction,

the (3-C)-th photoelectric conversion element, the (4-B)-th photoelectric conversion element, and the (3-D)-th photoelectric conversion element are arranged adjacently in the x₀ direction,

the (3-A)-th photoelectric conversion element, the (2-A)-th photoelectric conversion element, and the (3-C)-th photoelectric conversion element are arranged adjacently in the y₀ direction,

the (4-A)-th photoelectric conversion element, the first photoelectric conversion element, and the (4-B)-th photoelectric conversion element are arranged adjacently in the y₀ direction, and

the (3-B)-th photoelectric conversion element, the (2-B)-th photoelectric conversion element, and the (3-D)-th photoelectric conversion element are arranged adjacently in the y₀ direction.

[C01]

The light receiving device according to any one of [A01] to [B04], wherein a polarization element is configured as a wire grid polarization element.

[C02]

The light receiving device according to [C01], wherein a light transmissivity in a light transmission axis of the wire grid polarization element is equal to or greater than 80%.

[C03]

The light receiving device according to [C01], wherein an extinction ratio of the wire grid polarization element is equal to or greater than 10 and equal to or less than 1000.

[C04]

The light receiving device according to any one of [A01] to [C03], wherein a memory that is connected to photoelectric conversion parts and temporarily stores charges generated in the photoelectric conversion parts is formed in a semiconductor substrate.

[C05]

The light receiving device according to any one of [A01] to [C04], wherein a protective film is formed on the wire grid polarization element,

the wire grid polarization element has a line-and-space structure, and space parts of the wire grid polarization element are voids.

[C06]

The light receiving device according to [C05], wherein a second protective film is formed between the wire grid polarization element and the protective film, and n₁′>n₂′ is satisfied when a refractive index of a material forming the protective film is n₁′ and a refractive index of a material forming the second protective film is n₂′.

[C07]

The light receiving device according to [C06], wherein the protective film is formed of SiN and the second protective film is formed of SiO₂ or SiON.

[C08]

The light receiving device according to any one of [C05] to [C07], wherein a third protective film is formed on at least sides of line parts facing the space parts of the wire grid polarization element.

[C09]

The light receiving device according to any one of [C05] to [C08], further including a frame part surrounding the wire grid polarization element, wherein

the frame part is connected to the line parts of the wire grid polarization element, and

the frame part has the same structure as the line parts of the wire grid polarization element.

[C10]

The light receiving device according to any one of [C05] to [C09], wherein the line parts of the wire grid polarization element are composed of a laminated structure in which a light reflection layer formed of a first conductive material, an insulating film, and a light absorption layer formed of a second conductive material are laminated from a photoelectric conversion part side.

[C11]

The light receiving device according to [C10], wherein the light reflection layer and the light absorption layer are common in the photoelectric conversion elements.

[C12]

The light receiving device according to [C10] or [C11], wherein the insulating film is formed on the overall top face of the light reflection layer, and the light absorption layer is formed on the overall top face of the insulating film.

[C13]

The light receiving device according to any one of [C10] to [C12], wherein an underlying insulating layer is formed under the light reflection layer.

[C14]

The light receiving device according to any one of [C10] to [C13], wherein the insulating film is formed on the overall top face of the light reflection layer, and the light absorption layer is formed on the overall top face of the insulating film.

### REFERENCE SIGNS LIST

10A, 10B, 10C Photoelectric conversion element unit

11, 11₁, 11₂ Photoelectric conversion element (light receiving element, imaging element)

21 Photoelectric conversion part

22 Gate constituting memory

23 High-concentration impurity region constituting memory

24 Light shielding film

31 Silicon semiconductor substrate

32 Wiring layer

33 Lower interlayer insulating layer

34 Underlying insulating layer

35 Planarization film

36 Upper interlayer insulating layer

50, 50₁ 50₂, 50₃, 50₄ Wire grid polarization element

51A Light reflection layer formation layer

52 Insulating film

52A Insulating film formation layer

52a Cut part of insulating film

53 Light absorption layer

53A Light absorption layer formation layer

54 Line part (laminated structure)

55 Space part (gap between laminated structure and laminated structure)

56 Protective film

57 Second protective film

58 Third protective film

59 Frame part

71, 71₁, 71₂, 71₃, 71₄ Color filter layer

81 On-chip microlens

100 Solid-state imaging device

101 Photoelectric conversion part (light receiving part, imaging part)

111 Imaging area (effective pixel area)

112 Vertical driving circuit

113 Column signal processing circuit

114 Horizontal driving circuit

115 Output circuit

116 Driving control circuit

117 Signal line (data output line)

118 Horizontal signal line

200 Electronic apparatus (camera)

201 Solid-state imaging device

210 Optical lens

211 Shutter device

212 Driving circuit

213 Signal processing circuit

FD Floating diffusion layer

TRₘₑₘ Memory

TRₜᵣₛ Transfer transistor

TRᵣₛₜ Reset transistor

TRₐₘₚ Amplification transistor

TRₛₑₗ Select transistor

V_{DD} Power source

MEM Memory selection line

TG Transfer gate line

RST Reset line

SEL Selection line

VSL Signal line (data output line)

1. A light receiving device comprising:
a plurality of photoelectric conversion element units each composed of a first photoelectric conversion element including a first polarization element and a second photoelectric conversion element including a second polarization element; and
further comprising a polarized component measurement unit and a polarized component calculation unit, wherein
the first polarization element has a first polarization azimuth of an angle of α degrees,
the second polarization element has a second polarization azimuth of an angle of (α+90) degrees,
the polarized component measurement unit obtains a first polarized component of incident light on the basis of an output signal from the first photoelectric conversion element and obtains a second polarized component of the incident light on the basis of an output signal from the second photoelectric conversion element, and
the polarized component calculation unit calculates a polarized component of the second polarization azimuth in the obtained first polarized component on the basis of the obtained second polarized component and calculates a polarized component of the first polarization azimuth in the obtained second polarized component on the basis of the obtained first polarized component.

2. The light receiving device according to claim 1, wherein the polarized component calculation unit calculates a corrected first polarized component by subtracting a value obtained by multiplying an obtained value of the polarized component of the second polarization azimuth by a reciprocal of an extinction ratio from an obtained value of the first polarized component, and calculates a corrected second polarized component by subtracting a value obtained by multiplying an obtained value of the polarized component of the first polarization azimuth by the reciprocal of the extinction ratio from an obtained value of the second polarized component.

3. The light receiving device according to claim 1, wherein the first photoelectric conversion element and the second photoelectric conversion element are arranged in one direction.

4. A light receiving device comprising:
a plurality of photoelectric conversion element units each composed of a first photoelectric conversion element including a first polarization element, a second photoelectric conversion element including a second polarization element, a third photoelectric conversion element including a third polarization element, and a fourth photoelectric conversion element including a fourth polarization element; and
further comprising a polarized component measurement unit and a polarized component calculation unit, wherein
the first polarization element has a first polarization azimuth of an angle of α degrees,
the second polarization element has a second polarization azimuth of an angle of (α+45) degrees,
the third polarization element has a third polarization azimuth of an angle of (α+90) degrees,
the fourth polarization element has a fourth polarization azimuth of an angle of (α+135) degrees,
the polarized component measurement unit
obtains a first polarized component of incident light on the basis of an output signal from the first photoelectric conversion element,
obtains a second polarized component of the incident light on the basis of an output signal from the second photoelectric conversion element,
obtains a third polarized component of the incident light on the basis of an output signal from the third photoelectric conversion element, and
obtains a fourth polarized component of the incident light on the basis of an output signal from the fourth photoelectric conversion element, and
the polarized component calculation unit
calculates a polarized component of the third polarization azimuth in the obtained first polarized component on the basis of the obtained third polarized component,
calculates a polarized component of the first polarization azimuth in the obtained third polarized component on the basis of the obtained first polarized component,
calculates a polarized component of the fourth polarization azimuth in the obtained second polarized component on the basis of the obtained fourth polarized component, and
calculates a polarized component of the second polarization azimuth in the obtained fourth polarized component on the basis of the obtained second polarized component.

5. The light receiving device according to claim 4, wherein the polarized component calculation unit
calculates a corrected first polarized component by subtracting a value obtained by multiplying an obtained value of the polarized component of the third polarization azimuth by a reciprocal of an extinction ratio from an obtained value of the first polarized component,
calculates a corrected third polarized component by subtracting a value obtained by multiplying an obtained value of the polarized component of the first polarization azimuth by the reciprocal of the extinction ratio from an obtained value of the third polarized component,
calculates a corrected second polarized component by subtracting a value obtained by multiplying an obtained value of the polarized component of the fourth polarization azimuth by the reciprocal of the extinction ratio from an obtained value of the second polarized component, and
calculates a corrected fourth polarized component by subtracting a value obtained by multiplying an obtained value of the polarized component of the second polarization azimuth by the reciprocal of the extinction ratio from an obtained value of the fourth polarized component.

6. The light receiving device according to claim 4, wherein the plurality of photoelectric conversion elements are arranged in a two-dimensional matrix form in an x₀ direction and a y₀ direction,
a photoelectric conversion element unit is composed of a single first photoelectric conversion element, a single second photoelectric conversion element, a single third photoelectric conversion element, and a single fourth photoelectric conversion element,
the first photoelectric conversion element and the second photoelectric conversion element are arranged in the x₀ direction,
the third photoelectric conversion element and the fourth photoelectric conversion element are arranged in the x₀ direction,
the first photoelectric conversion element and the fourth photoelectric conversion element are arranged in the y₀ direction, and
the second photoelectric conversion element and the third photoelectric conversion element are arranged in the y₀ direction.

7. The light receiving device according to claim 4, wherein the plurality of photoelectric conversion elements are arranged in a two-dimensional matrix form in the x₀ direction and the y₀ direction,
a photoelectric conversion unit is composed of a single first photoelectric conversion element, two second photoelectric conversion elements including a (2-A)-th photoelectric convention element and a (2-B)-th photoelectric conversion element, four third photoelectric conversion elements including a (3-A)-th photoelectric convention element, a (3-B)-th photoelectric conversion element, a (3-C)-th photoelectric convention element, and a (3-D)-th photoelectric conversion element, and two fourth photoelectric conversion elements including a (4-A)-th photoelectric conversion element and a (4-B)-th photoelectric conversion element,
the (3-A)-th photoelectric conversion element, the (4-A)-th photoelectric conversion element, and the (3-B)-th photoelectric conversion element are arranged adjacently in the x₀ direction,
the (2-A)-th photoelectric conversion element, the first photoelectric conversion element, and the (2-B)-th photoelectric conversion element are arranged adjacently in the x₀ direction,
the (3-C)-th photoelectric conversion element, the (4-B)-th photoelectric conversion element, and the (3-D)-th photoelectric conversion element are arranged adjacently in the x₀ direction,
the (3-A)-th photoelectric conversion element, the (2-A)-th photoelectric conversion element, and the (3-C)-th photoelectric conversion element are arranged adjacently in the y₀ direction,
the (4-A)-th photoelectric conversion element, the first photoelectric conversion element, and the (4-B)-th photoelectric conversion element are arranged adjacently in the y₀ direction, and
the (3-B)-th photoelectric conversion element, the (2-B)-th photoelectric conversion element, and the (3-D)-th photoelectric conversion element are arranged adjacently in the y₀ direction.

8. The light receiving device according to claim 1, wherein a polarization element is configured as a wire grid polarization element.

9. The light receiving device according to claim 8, wherein a light transmissivity in a light transmission axis of the wire grid polarization element is equal to or greater than 80%.

10. The light receiving device according to claim 8, wherein an extinction ratio of the wire grid polarization element is equal to or greater than 10 and equal to or less than 1000.

11. The light receiving device according to claim 4, wherein a polarization element is configured as a wire grid polarization element.

12. The light receiving device according to claim 11, wherein a light transmissivity in a light transmission axis of the wire grid polarization element is equal to or greater than 80%.

13. The light receiving device according to claim 11, wherein an extinction ratio of the wire grid polarization element is equal to or greater than 10 and equal to or less than 1000.
